(19) United States
(12) Patent Application Publication
(10) Pub. No.: US 2026/0271437 A1
(43) Pub. Date: Sep. 10, 2026

(54) LIGHT EMITTING ELEMENT AND DISPLAY DEVICE

(71) Applicant: Sharp Display Technology Corporation, Kameyama City, Mie (JP)

(72) Inventor: YOSHIHIRO UETA, Sakai City, Osaka (JP)

(21) Appl. No.: 19/102,981

(22) PCT Filed: Aug. 29, 2022
(86) PCT No.: PCT/JP2022/032331

§ 371 Date: Feb. 11, 2025

(51) Int. Cl. H10H 20/81; C09K 11/02; H10H 20/01; H10H 20/812; H10H 20/813; H10H 20/823; H10H 29/01; H10K 50/115; H10K 50/12; H10K 59/12; H10K 71/15; H10K 71/30

(52) U.S. Cl. CPC H10H 20/8215; C09K 11/025; H10H 20/012; H10H 20/812; H10H 20/8133; H10H 20/8232; H10K 50/115; H10K 50/12; H10K 71/15; H10K 71/30; H10H 29/012; H10K 59/1201

(57) ABSTRACT

A light-emitting element includes an EML and an HTL, in which the EML includes a base material and a plurality of QDs, the base material includes a base compound including at least one kind of first group VI element as a main component and includes at least one kind of second group VI element having a smaller period number than the first group VI element, and a concentration of the sum of the second group VI elements in the base material is in a range from 1×10¹⁶ atoms/cm³ to 1×10²⁰ atoms/cm³.

### TECHNICAL FIELD

The disclosure relates to a light-emitting element and a display device.

### BACKGROUND ART

In a light-emitting element using a quantum dot as a light-emitting material in a light-emitting layer, generally, an injection amount of electrons is greater than an injection amount of holes in the light-emitting layer, so that there has been a problem of excessive electron supply and shortage of holes. Further, in general, on a surface of the quantum dot, an organic ligand is used for the purpose of protecting the quantum dot and improving dispersibility of the quantum dot in a solvent. However, the organic ligand composed of an organic matter is easily deteriorated and causes a decrease in reliability.

InP-Quantum-Dot-in-ZnS-Matrix Solids for Thermal and Air Stability, Chemical Material, 2020, 32, 22, 9584-9590 discloses a quantum dot protected with a sulfide instead of the organic ligand. When the light-emitting layer is mineralized by, for example, protecting the quantum dot with the sulfide or the like as described above, the organic matter that is easily deteriorated can be eliminated, and reliability is improved.

### SUMMARY

### Technical Problem

However, even when the light-emitting layer is mineralized, excessive electrons remains unchanged.

An aspect of the disclosure has been contrived in view of the above problem, and an object of the disclosure is to provide a light-emitting element and a display device which have high reliability, can improve a carrier balance between holes and electrons, and have excellent light-emitting characteristics.

### Solution to Problem

In order to solve the above problem, a light-emitting element according to an aspect of the disclosure includes a light-emitting layer and a hole transport layer provided adjacent to the light-emitting layer, in which the light-emitting layer includes a base material including at least one kind of inorganic compound and a plurality of quantum dots, the base material includes, as the inorganic compound, a base compound including at least one kind of first group VI element as a main component and includes at least one kind of second group VI element having a smaller period number than the first group VI element included in the base compound, and a concentration of the sum of the second group VI elements in the base material is in a range from 1×10¹⁶ atoms/cm³ to 1×10²⁰ atoms/cm³.

In order to solve the problems described above, a display device according to an aspect of the disclosure includes the above-described light-emitting element according to an aspect of the disclosure.

### Advantageous Effects of Disclosure

According to an aspect of the disclosure, a light-emitting element and a display device which have high reliability, can improve a carrier balance between holes and electrons, and have excellent light-emitting characteristics can be provided.

### BRIEF DESCRIPTION OF DRAWINGS

FIG. 1 is a cross-sectional view illustrating a schematic configuration of a light-emitting element according to a first embodiment.

FIG. 2 is a cross-sectional view illustrating a schematic configuration of a quantum dot and its vicinity in the light-emitting element illustrated in FIG. 1.

FIG. 3 is a cross-sectional view illustrating a state in which quantum dots adjacent to each other are close to each other in the light-emitting element illustrated in FIG. 1.

FIG. 4 is a schematic view illustrating an example of a band structure of each function layer when each function layer between an anode electrode and a cathode electrode is in an isolated state in the light-emitting element illustrated in FIG. 1.

FIG. 5 is a schematic view illustrating an example of a band structure of each function layer in a state in which the function layers illustrated in FIG. 4 are bonded to each other and band-shifted so that the Fermi levels coincide with each other.

FIG. 6 is a schematic view illustrating an example of a band structure of each function layer when each function layer between an anode electrode and a cathode electrode is in an isolated state in a light-emitting element for comparison.

FIG. 7 is a schematic view illustrating an example of a band structure of each function layer in a state in which the function layers illustrated in FIG. 6 are bonded to each other and band-shifted so that the Fermi levels coincide with each other.

FIG. 8 is a graph showing J-V characteristics of the light-emitting element according to the first embodiment and J-V characteristics of a light-emitting element for comparison.

FIG. 9 is a graph showing light-emitting characteristics of the light-emitting element according to the first embodiment and light-emitting characteristics of the light-emitting element for comparison.

FIG. 10 is another graph showing light-emitting characteristics of the light-emitting element according to the first embodiment and light-emitting characteristics of the light-emitting element for comparison.

FIG. 11 is a flowchart showing an example of a manufacturing method for the light-emitting element according to the first embodiment.

FIG. 12 is a schematic cross-sectional view for describing a ligand substitution step illustrated in FIG. 11.

FIG. 13 is a cross-sectional view illustrating a schematic configuration of a quantum dot dispersion used for forming the light-emitting element according to the first embodiment.

FIG. 14 is a cross-sectional view of steps illustrating an example of a method of forming a light-emitting layer of the light-emitting element according to the first embodiment.

FIG. 15 is a cross-sectional view illustrating a schematic configuration of a light-emitting element according to a second embodiment.

FIG. 16 is a schematic view illustrating an example of a band structure of each function layer when a second group VI element is mixed only into a first portion of a first light-emitting layer and each function layer between an anode electrode and a cathode electrode is in an isolated state in the light-emitting element illustrated in FIG. 15.

FIG. 17 is a schematic view illustrating an example of a band structure of each function layer in a state in which the function layers illustrated in FIG. 16 are bonded to each other and band-shifted so that the Fermi levels coincide with each other.

FIG. 18 is a cross-sectional view illustrating an example of a schematic configuration of a light-emitting element according to a modified example of the second embodiment.

FIG. 19 is a plan view illustrating a configuration example of a display device according to a third embodiment.

### DESCRIPTION OF EMBODIMENTS

### First Embodiment

Hereinafter, embodiments of the disclosure will be described in detail. Note that, in the following, description of “from A to B” for two numbers A and B means “being equal to or greater than A and equal to or less than B”, unless otherwise specified. Further, in the following, a layer formed in a process prior to that of a layer being compared is referred to as a “lower layer”, and a layer formed in a process after that of a layer being compared is referred to as an “upper layer”.

In the disclosure, an “organic material” or an “organic compound” indicates a substance in which carbon is a center of an atomic bond, and an “inorganic material” or an “inorganic compound” indicates a substance other than an organic substance. Thus, in the disclosure, the “inorganic material” or the “inorganic compound” is desirably considered to indicate a substance in which carbon is not contained in the atomic bond. It may also be a substance in which carbon is not contained in the center of the atomic bond. Furthermore, it is not excluded to consider that the substance does not contain a carbon chain.

In the following, for convenience of description, members having the same functions as the members described earlier may be denoted by the same reference numerals and signs, and the description thereof will not be repeated. Differences from the embodiment described above will be described in the embodiment described below. It goes without saying that similar modifications to those of the embodiment described above can be made even unless otherwise explained. Overall Configuration of Light-Emitting Element A light-emitting element according to the present embodiment includes a light-emitting layer and a hole transport layer provided adjacent to the light-emitting layer, and the light-emitting layer contains a base material containing at least one kind of inorganic compound and a plurality of quantum dots.

In the following, a case where the light-emitting element has a known structure in which an anode electrode is a lower layer electrode and a cathode electrode is an upper layer electrode, and includes a hole transport layer, a light-emitting layer, and an electron transport layer as function layers between the anode electrode and the cathode electrode will be described as an example. Note that in the disclosure, the layers between the anode electrode and the cathode electrode are collectively called a function layer.

However, the light-emitting element according to the present embodiment is not limited thereto, and may include the light-emitting layer and the hole transport layer provided adjacent to the light-emitting layer as the function layer. The light-emitting element according to the present embodiment may have an inverted structure in which the cathode electrode is a lower layer electrode and the anode electrode is an upper layer electrode, for example.

Hereinafter, the light-emitting layer may be referred to as “EML”, the hole transport layer may be referred to as “HTL”, and the electron transport layer may be referred to as “ETL”. The quantum dot may be referred to as “QD”.

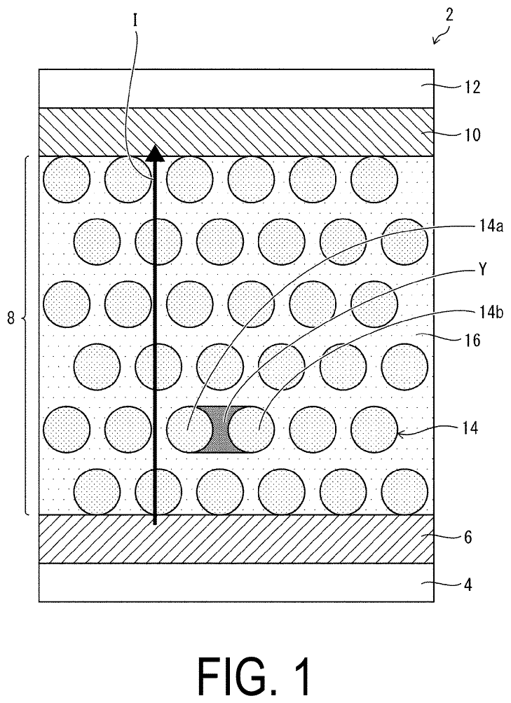

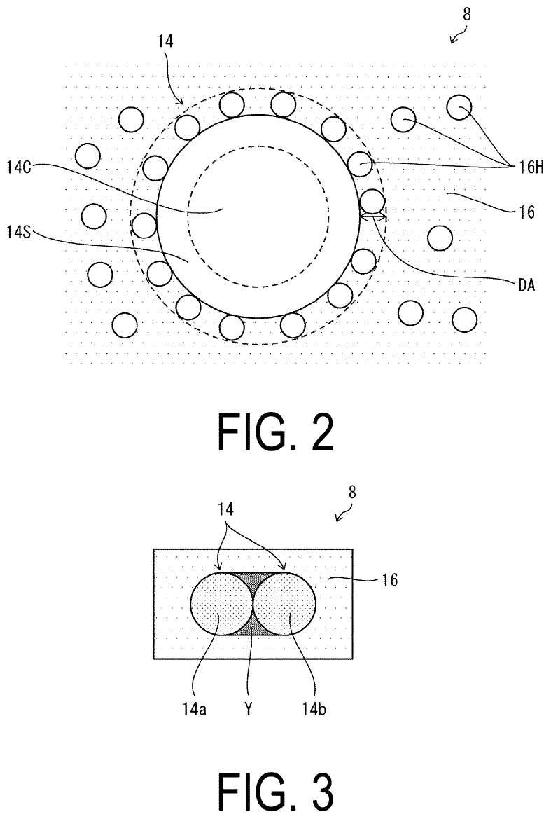

FIG. 1 is a cross-sectional view illustrating a schematic configuration of a light-emitting element 2 according to the present embodiment. FIG. 2 is a cross-sectional view illustrating an example of a schematic configuration of a QD 14 and its vicinity in the light-emitting element 2 illustrated in FIG. 1. FIG. 3 is a cross-sectional view illustrating a state in which adjacent ones of the QDs 14 are close to each other in the light-emitting element 2 illustrated in FIG. 1.

As illustrated in FIG. 1, the light-emitting element 2 according to the present embodiment has, as an example, a configuration in which an anode electrode 4, an HTL 6, an EML 8, an ETL 10, and a cathode electrode 12 are provided in this order from a lower layer side (e.g., a side of a support body not illustrated such as a substrate). Each layer from the anode electrode 4 to the cathode electrode 12 is generally supported by a substrate as a support body. Note that although illustration and description are omitted, the light-emitting element 2 may include a function layer not illustrated other than the HTL 6, the EML 8, and the ETL 10 between the anode electrode 4 and the cathode electrode 12. As an example, for example, in the light-emitting element 2, a hole injection layer having a hole transport property and promoting injection of holes from the anode electrode 4 to the HTL6 may be provided between the anode electrode 4 and the HTL6. Note that, hereinafter, the hole injection layer may be referred to as “HIL”.

At least one of the anode electrode 4 and the cathode electrode 12 is a light-transmissive electrode. Note that any one of the anode electrode 4 and the cathode electrode 12 may be a so-called reflective electrode having light reflectivity. In the light-emitting element 2, light can be extracted from the side of the light-transmissive electrode.

For example, in a case where the light-emitting element 2 is a top-emission type light-emitting element that emits light from an upper layer electrode side, a light-transmissive electrode is used as the upper layer electrode, and a reflective electrode is used as the lower layer electrode. On the other hand, in a case where the light-emitting element 2 is a bottom-emission type light-emitting element that emits light from a lower layer electrode side, a light-transmissive electrode is used as the upper layer electrode, and a reflective electrode is used as the lower layer electrode. For the light-transmissive electrode, for example, a conductive material that transmits visible light, such as indium tin oxide (ITO), indium zinc oxide (IZO), ZnO, aluminum-doped zinc oxide (AZO, also referred to as ZAO), boron-doped zinc oxide (BZO), or fluorine-doped tin oxide (FTO), is used.

For the reflective electrode, for example, a conductive material having a high reflectivity of visible light, for example, a metal such as Al, Cu, Au, Ag, or MgAg, or an alloy containing these metals is preferably used.

The HTL6 is a charge transport layer that contains a hole transport material and has a hole transport function of transporting holes (h⁺, see FIG. 5 described later) injected from the anode electrode 4 into the EML 8. As the hole transport material, an organic material or an inorganic material employed, in related art, in a quantum dot light-emitting diode (QLED) which is a light-emitting element containing QDs, an organic light-emitting diode (OLED), or the like can be used.

As the organic material of the HTL 6, for example, a conductive compound such as 4,4′-bis(carbazol-9-yl) biphenyl (CBP), polyphenylenevinylene (PPV), a composite (PEDOT: PSS) of poly(3,4-ethylenedioxythiophene) (PEDOT) and polystyrene sulfonate (PSS), poly[(9,9-dioctylfluorenyl-2,7-diyl)-co-(4,4′-(N-4-sec-butylphenyl)diphenylamine)]) (TFB), or polyvinyl carbazole (PVK) can be used.

As the inorganic material of the HTL 6, for example, a metal oxide such as a molybdenum oxide, NiO, Cr₂O₃, MgO, MgZnO, LaNiO₃, or WO₃ can be used. In particular, as the material of the HTL 6, a material having a large electron affinity and ionization potential is suitable.

The ETL 10 is a charge transport layer that contains an electron transport material and has an electron transport function of transporting electrons (e″, see FIG. 5 described later) injected from the cathode electrode 12 into the EML 8. As the electron transport material, for example, in addition to TiO₂, an organic or inorganic material employed, in related art, in the QLED, OLED, or the like can be used.

As the organic material of the ETL 10, for example, a conductive compound such as tris(8-quinolinol)aluminum complex (Alq3), bathocuproine (BCP), or (2-(4-biphenylyl)-5-(4-tert-butylphenyl)-1,3,4-oxadiazole) (t-Bu-PBD) can be used.

As the inorganic material of the ETL 10, for example, ZnO, AZO, ITO, In—Ga—Zn—O based semiconductors (for example, indium gallium zinc oxide), or metal oxides such as electride can be used. In particular, as the material of the ETL 10, a material having a small electron affinity is suitable.

The EML 8 includes a base material 16 containing at least one kind of inorganic compound, and a plurality of the QDs 14. In the disclosure, removing the organic ligand and embedding the QD 14 in the base material 16 containing the inorganic compound is referred to as mineralizing the EML 8. Further, the EML 8 containing the base material 16 containing the inorganic compound may be referred to as a mineralized EML 8.

In the EML 8, a hole transported from the anode electrode 4 and an electron transported from the cathode electrode 12 are recombined, and an exciton generated by this emits light in a process of transitioning from a conduction band level to a valence band level of the QD 14. The EML 8 includes a nano-size QD 14 corresponding to a luminescent color as a light-emitting material.

The QD 14 is a dot having a particle maximum width of 100 nm or less. The QD 14 generally has a composition derived from a semiconductor material, and thus may also be called a semiconductor nanoparticle. Further, the QD 14 generally has a composition derived from an inorganic material, and thus may also be referred to as an inorganic nanoparticle. Further, the QD 14 has a specific crystal structure, for example, and thus may also be called a nanocrystal.

The shape of the QD 14 is not particularly limited as long as it is within a range satisfying the maximum width, and the shape thereof is not limited to a spherical three-dimensional shape (circular cross-sectional shape). The shape of the QD 14 may be, for example, a polygonal cross-sectional shape, a rod-shaped three-dimensional shape, a branch-shaped three-dimensional shape, or a three-dimensional shape having unevenness on the surface thereof, or a combination of them.

The QD 14 may contain at least one metal element. Examples of the metal element contained in the QD 14 include Cd, Zn, In, Sb, Al, Si, Ga, Pb, Ge, and Mg. The QD 14 may be a semiconductor material in which at least one metal element and a non-metal element such as S, Te, Se, N, P, and As are combined.

The QD 14 may be formed only of a core, and may be of a two-component core type, of a three-component core type, or of a four-component core type. As illustrated in FIG. 2, the QD 14 may have a core-shell structure including a core 14C and a shell 14S, and may be a core-shell type or a core-multi-shell type.

As illustrated in FIG. 2, in a case where the QD 14 includes the shell 14S, it is sufficient for the shell 14S to be provided on the surface of the core 14C, the core 14C being centrally located. Although the shell 14S desirably covers the entire core 14C, the shell 14S need not necessarily completely cover the core 14C. The shell 14S may be formed on a part of the surface of the core 14C. The QD 14 can be said to have the core-shell structure if it is found that the shell 14S is formed on a part of the surface of the core 14C, or it is found that the shell 14S envelopes the core 14C, in an observation of a cross-section of the QD 14. Accordingly, it is sufficient to determine that the shell 14S covers the entire core 14C by an observation of a cross-section of the QD 14. Note that the cross-sectional observation can be performed by, for example, a scanning transmission electron microscope (STEM) or a transmission electron microscope (TEM).

The QD 14 may also include doped nanoparticles or include a compositionally graded structure. The shell 14S may be formed in a state of solid solution on the surface of the core 14C. In FIG. 2, the boundary between the core 14C and the shell 14S is indicated by a dotted line, which indicates that it does not matter whether the boundary between the core 14C and the shell 14S is confirmed or not confirmed by analysis. The shell 14S may be formed in a plurality of layers.

In the QD 14, materials of the core 14C and the shell 14S may contain materials used for the core material and the shell material of a known QD, respectively. The core 14C may be formed of, for example, Si, Ge, CdSe, CdS, CdTe, InP, GaP, InN, ZnSe, ZnS, ZnTe, CdSeTe, GalnP, ZnSeTe, or the like. The shell 14S may be formed of, for example, CdS, ZnS, CdSSe, CdTeSe, CdSTe, ZnSSe, ZnSTe, ZnTeSe, AIP, or the like. As an example, when the shell 14S contains ZnSSe, ZnSSe contained in the shell 14S may be ZnSₓSe₁₋ₓ (0≤x≤1). When the QD 14 has the core-shell structure, examples of the material of the QD 14 (combination of materials of core 14C/shell 14S) include ZnSe/ZnS, InP/ZnS, CdSe/CdS, CdSe/ZnSe, and CIGS/ZnS.

A composition represented by a chemical formula in the disclosure is desirably stoichiometric. However, other than stoichiometry is not excluded.

The QDs 14 can have light emission wavelengths changed variously depending on, for example, particle sizes and compositions thereof. The QD 14 is a QD that emits visible light, and the emission wavelength can be controlled from a blue wavelength region to a red wavelength region by appropriately adjusting the particle size and composition of the QD 14.

The core 14C of the QD 14 is a light-emitting material that has a valence band level and a conduction band level and emits light through recombination between holes in the valence band level and electrons in the conduction band level. Because light emitted from the QD 14 has a narrower spectrum due to a quantum confinement effect, it is possible to obtain the emitted light with relatively deep chromaticity.

The QDs 14 in the EML 8 do not need to be regularly arranged as illustrated in FIG. 1, and the QDs 14 may be randomly included in the EML 8. In the EML 8, the QDs 14 may be in a state in which the base material 16 is formed between the adjacent ones of the QDs 14, and the QDs 14 are not close to each other as illustrated in FIG. 1, or the EML 8 may include two or more QDs 14 close to each other as illustrated in FIG. 3. A layer thickness of the EML 8 may be about 1 nm or more and about 100 nm or less, and is preferably about 10 nm or more and about 60 nm or less.

In the disclosure, the base material means a member that contains and holds other materials, and can be rephrased as a matrix material or a filler material. That is, in the disclosure, the base material 16 refers to as a member that contains and holds the QD 14. The base material 16 is an element constituting a film in which the QDs 14 are distributed, and is one of a constituent element of the EML 8 including the plurality of QDs 14 as illustrated in FIG. 1. The base material 16 may be solid at room temperature.

The EML 8 may be filled with the base material 16. As illustrated in FIG. 1, paying attention to two QDs 14 among the plurality of QDs 14, the base material 16 may fill a space between the two QDs 14 (that is, a region Y (space) between the two QDs 14). When the two QDs 14 are respectively defined as a first QD 14a and a second QD 14b, the region Y is a region surrounded by two straight lines (common outer tangent lines) in contact with the outer peripheries of the first QD 14a and the second QD 14b and the opposing outer peripheries of the first QD 14a and the second QD 14b in a cross-sectional view.

FIG. 1 illustrates an example in which the QDs 14 are embedded in the base material 16 at intervals. However, as described above, in the EML 8, the adjacent ones of the QDs 14 need not be close to each other, or may be close to each other. As illustrated in FIG. 3, even when the first QD 14a and second QD 14b adjacent to each other are close to each other, the region Y (space) may exist between the first QD 14a and second QD 14b. Even when the first QD 14a and the second QD 14b are close to each other, the base material 16 may fill the region Y (space) between the first QD 14a and the second QD 14b.

Thus, the base material 16 may fill a region (space) other than the QDs 14 in the EML 8. Thus, the region (space) other than the QDs 14 may be embedded in the base material 16 in the EML 8. The EML 8 may include a QD group (quantum dot group) including the plurality of QDs 14, and the base material 16 may fill a region (space) other than the QD group in the EML 8. Here, three or more QDs 14 are collectively referred to as the QD group. The region (space) other than the plurality of QDs 14 may be embedded in the base material 16 in the EML 8. Outer edges (upper face and lower face) of the EML 8 may be covered with the base material 16. Alternatively, there may be a portion of the base member 16 from the outer edge of the EML 8, and the QDs 14 may be located away from the outer edge of the EML 8. The outer edge of the EML 8 need not be formed only of the base material 16, and a part of the QD 14 may be exposed from the base material 16. The base material 16 may be referred to as a portion of the EML 8 excluding the QDs 14.

The base material 16 may include the plurality of QDs 14. The base material 16 may be formed such that a space between the plurality of QDs 14 (that is, a space formed between the plurality of QDs 14) is filled with the base material 16. The space between the plurality of QDs 14 may be partially or completely filled with the base material 16.

The base material 16 may include a continuous film having an area of 1000 nm² or more in a plane direction orthogonal to a layer thickness direction. The continuous film means a film that is not separated by a material other than a material constituting the continuous film in one plane. The continuous film may be in a form of an integral film connected by chemical bonding of the material constituting the base material 16 without interruption.

The base material 16 may contain the same material as that of the shell 14S included in each of the plurality of QDs 14. In other words, the shell 14S may contain the same material as a base compound of the base material 16. When the shell 14S contains the same material as the base compound of the base material 16, the shell 14S and the base compound of the base material 16 are continuously connected to each other, and thus qualities of the base material 16 can be improved.

As described above, when the base material 16 contains the same material as the shell 14S, an average distance between adjacent ones of the cores 14C (core-to-core distance) may be 3 nm or more, and also may be 5 nm or more in order for QDs 14 to avoid being brought in contact with each other and to avoid aggregation of the QDs 14. Alternatively, the average distance between adjacent ones of the cores 14C may be 0.5 times or more the average core diameter. The core-to-core distance is an average of distances between adjacent cores in a space including 20 cores. The core-to-core distance may be kept wider than the distance when the shells 14S are in contact with each other. The average core diameter is obtained by averaging the core diameters of 20 cores 14C in the cross-sectional observation in a space including the 20 cores. The core diameter can be the diameter of a circle having the same area as the core area in the cross-sectional observation.

A concentration of the base material 16 in the EML 8 is, for example, an area ratio occupied by the base material 16 in a cross section of the EML 8. The concentration of the base material 16 may be 10% or more and 90% or less, or may be 30% or more and 70% or less in the cross-sectional observation of the EML 8. The concentration of the base material 16 may be measured by, for example, an area ratio in image processing in the cross-sectional observation of the EML 8. When the QD 14 has the core-shell structure, a concentration of the shell 14S may be 1% or more and 50% or less. When the shell 14S and the base material 16 are made of the same material (the same composition) and the shell 14S and the base material 16 cannot be distinguished from each other, a concentration of a combined region of the shell 14S and the base material 16 may be in a numerical range obtained by adding a numerical range of the concentration of the shell 14S to a numerical range of the concentration of the base material 16. A total of ratios of the core 14C and the shell 14S of the QD 14 and the base material 16 may be adjusted to be 100% or less as appropriate. As described above when the shell 14S and the base material 16 cannot be distinguished from each other, the shell 14S may be a part of the base material 16.

The EML 8 may be made of the plurality of QDs 14 and the base material 16. When the EML 8 is analyzed, an intensity of carbon detected by a chain structure may be a noise level or less.

A constituent material of the base material 16 desirably has a band gap (hereinafter referred to as “Eg”) wider than an Eg of a constituent material of the QD 14. For example, as described above, when the QD 14 includes the core 14C and the shell 14S, the Eg of the base material 16 is desirably larger than an Eg of the core 14C or the shell 14S.

Recombination between carriers (an electron and a hole) injected into the QD 14 occurs mainly in the core 14C. The shell 14S has functions of suppressing generation of a defect, a dangling bond, or the like in the core 14C and reducing recombination of carriers through a deactivation process. When the Eg of the base material 16 is larger than Eg of the core 14C or the shell 14S, a confinement effect of confining the excitons in the core 14C is high, and excitons generated by recombination of carriers or light absorption in the core 14C are less likely to diffuse into the base material 16, so that a luminous efficiency of the light-emitting element 2 can be improved.

The Eg of the base material 16 may be equal to the Eg of the shell 14S or smaller than the Eg of the shell 14S as long as the Eg of the base material 16 is larger than the Eg of the core 14C. However, the Eg of the base material 16 is preferably larger than the Eg of the shell 14S. In this case, the confinement effect of confining the exciton in the core 14C is higher, diffusion of the excitons from the QD 14 to the base material 16 is suppressed, and the luminous efficiency can be further improved.

The base material 16 contains at least one kind of inorganic compound. The inorganic compound (inorganic material) constituting the base material 16 may be a semiconductor material or may be an insulator material.

In addition, a main material of the base material 16 may be an inorganic compound, and it is not excluded that a material different from the inorganic compound used as the main material is added as an additive.

The base material 16 contains, as the inorganic compound, the base compound containing at least one kind of group VI element (first group VI element) as a main component and contains a group VI element (second group VI element) having a period number smaller than a period number of the first group VI element. The base material 16 may contain a substance different from the base compound as an additive, for example.

In the disclosure, a notation of a group number of an element using a Roman numeral is based on the old IUPAC system, and the group VI element includes a group VIA element and a group VIB element. Thus, the group VI element means a group 6 element and a group 16 element according to a notation based on the new IUPAC system. In the disclosure, a notation of a group number of an element using an Arabic numeral indicates a notation based on the new IUPAC system. The group number in the old IUPAC system is consistent with the formal valence electron number.

Specific examples of the group VIA element include chromium (Cr), molybdenum (Mo), tungsten (W), and seaborgium (Sg) in ascending order of the periodic number. Specific examples of the group VIB element include oxygen (O), sulfur(S), selenium (Se), tellurium (Te), polonium (Po), and livermorium (Lv) in ascending order of the periodic number. O belongs to the second period, S belongs to the third period, Cr and Se belong to the fourth period, Mo and Te belong to the fifth period, W and Po belong to the sixth period, and Sg and Lv belong to the seventh period.

When the first group VI element belongs to the m-th period (m is an integer of 2 or more), a group VI element belonging to an (m-k)-th period (k is an integer of 1 or more and m-1 or less) is used as the second group VI element.

The base compound is preferably a group II-VI compound. A group II element includes a group IIA element and a group IIB element, and means a group 2 element and a group 12 element. In the disclosure, the group II-VI compound may contain the group II element and the group VI element in a composition ratio of about 1:1, or may contain more than 1:1 of the group VI element to the group II element. That is, the base compound may contain the group II-VI compound in which the group VI element is excessive.

Examples of the base compound include a compound containing one or more kind of group II elements selected from magnesium (Mg), zinc (Zn), cadmium (Cd), and mercury (Hg), and one or more kind of group VI elements selected from O, S, Se, and Te.

In order to maintain or enhance the confinement of the exciton to the core 14C of the QD 14, as described above, the base compound desirably has the Eg equal to or wider than the core 14C or the shell 14S of the QD 14, and more desirably has the Eg equal to or wider than the shell 14S. Further, in order to improve the qualities of the base material 16, the shell 14S of the QD 14 and a crystal of the base material 16 are desirably continuously connected. Alternatively, the shell 14S of the QD 14 and the base material 16 may be amorphous. Thus, as the base compound, the group II-VI compound generally used for the shell of the QD is suitable, and the same material as that of the shell 14S of the QD 14 is desirably used for the base material 16, particularly the base compound.

The first group VI element may be any group VI element other than O, but is desirably at least one kind selected from the group consisting of S, Se, and Te. Among the group II-VI compounds, S, Se, and Te are commonly used in the shell of the QD and are particularly suitable as the base compound. As described above, the base material 16 contains the base compound containing the at least one kind of the first group VI element as the main component and contains the second group VI element having the period number smaller than the period number of the first group VI element. O is excluded from the first group VI element because O has the smallest period number among the group VI elements.

Examples of the group II-VI compound include magnesium sulfide (MgS), magnesium selenide (MgSe), zinc sulfide (ZnS), zinc selenide (ZnSe), zinc telluride (ZnTe), cadmium selenide (CdSe), cadmium telluride (CdTe), mercury sulfide (HgS), mercury selenide (HgSe), mercury telluride (HgTe), cadmium selenide sulfide (CdSeS), cadmium selenide telluride (CdSeTe), cadmium sulfur telluride (CdSTe), zinc selenium sulfide (ZnSeS), zinc selenium telluride (ZnSeTe), zinc tellurium sulfide (ZnTeS), mercury selenium sulfide (HgSeS), tellurium compound mercury selenium (HgSeTe), mercury sulfur telluride (HgSTe), cadmium zinc sulfide (CdZnS), cadmium zinc selenide (CdZnSe), cadmium zinc telluride (CdZnTe), cadmium mercury sulfide (CdHgS), cadmium mercury selenide (CdHgSe), cadmium mercury telluride (CdHgTe), mercury zinc sulfide (HgZnS), mercury zinc selenide (HgZnSe), mercury zinc telluride (HgZnTe), magnesium zinc selenide (MgZnSe), magnesium zinc sulfide (MgZnS), mercury zinc tellurium sulfide (HgZnTeS), cadmium zinc selenium sulfide (CdZnSeS), cadmium zinc selenium telluride (CdZnSeTe), cadmium zinc sulfur telluride (CdZnSTe), cadmium mercury selenium sulfide (CdHgSeS), cadmium mercury selenium telluride (CdHgSeTe), cadmium mercury sulfur telluride (CdHgSTe), mercury zinc selenium sulfide (HgZnSeS), mercury zinc selenium telluride (HgZnSeTe), mercury zinc sulfur telluride (HgZnSTe), and mixtures thereof. As described above, the group II-VI compound is not limited to a binary compound, and may be a ternary or quaternary compound. Note that a chemical formula written within parentheses after a compound name is a representative example. As described above, the composition ratio described in the chemical formula is desirably stoichiometry in which the actual composition of the compound is the same as the chemical formula but is not necessarily stoichiometry.

As indicated in the above examples, the group II-VI compound used for the base compound may contain, for example, a metal sulfide. In particular, the shell 14S is often ZnS. As described above, the same material as the shell 14S of the QD 14 is desirably used for the base compound. Thus, when the shell 14S is ZnS, ZnS is preferably used as the base compound. The band gap of ZnS is 3.6 eV.

However, the present embodiment is not limited to this. In general, similarly to ZnS, a metal sulfide such as ZnMS containing a metal element M other than Zn is preferably used for the shell of the QD. Thus, the group II-VI compound used for the base compound may be the metal sulfide such as ZnMS containing the metal element M other than Zn. The metal element M is desirably upper than Zn in the periodic table, such as Mg or Li.

As described above, the base material 16 may be a mixed crystal of a metal sulfide containing a first element and a metal sulfide containing a second element, and the base material 16 may be a mixed crystal abc in which a compound bc containing an element b and an element c is mixed with a compound ac containing an element a and the element c. When the base material 16 contains the mixed crystal of the metal sulfide containing the first element and the metal sulfide containing the second element as the base compound, for example, the first element may be Zn and the second element may be Mg or lithium (Li).

As described above, the base material 16 may contain Mg or Li, or a mixture of Mg and Li. Mg and Li belong to an upper period having a period number smaller than a period number of Zn. Thus, when one or both of Mg and Li are contained at a composition level, the Eg of the base material 16 is widened, and a current flowing outside the QD 14 is suppressed. Thus, when the base material 16 contains at least one of Mg and Li, an injection efficiency of holes into the QD 14 can be improved, and the luminous efficiency can be further improved.

These Mg and Li are desirably contained in the base material 16 at the composition level. That is, Mg and Li desirably form a part of the composition of the base material 16. Thus, when the base material 16 contains at least one of Mg and Li, a lower limit of a concentration of a sum of Mg and Li contained in the base material 16 is desirably 1×10²¹ atoms/cm³. On the other hand, when the base material 16 contains, for example, a mixed crystal ZnMgS of ZnS and MgS or a mixed crystal ZnLiS of ZnS and LiS, crystal systems of MgS and LiS are different from that of ZnS, and thus an upper limit of a composition of Mg or Li or a total of Mg and Li in the ZnS base in the base material 16 is 10%. Thus, in terms of concentration, when the base material 16 contains at least one of Mg and Li, the upper limit of the concentration of the sum of Mg and Li contained in the base material 16 is 1×10²² atoms/cm³. Thus, when the base material 16 contains at least one of Mg and Li, the concentration of the sum of Mg and Li contained in the base material 16 is desirably 1×10²¹ atoms/cm³ or more and 1×10²² atoms/cm³ or less.

The second group VI element is a dopant mixed (doped) into the base compound as an impurity element (additive), and the concentration of the sum of the second group VI elements in the base material 16 is in a range from 1×10¹⁶ atoms/cm³ to 1×10²⁰ atoms/cm³.

As described above, the group VI element having the period number smaller than the period number of the first group VI element is used as the second group VI element. Thus, when the base compound is, for example, ZnS as described above, S, which is a group VI element, belongs to the third period, and thus O, which is a group VI element belonging to the second period, is used as the second group VI element. In this case, the base material 16 contains two kinds of the group VI elements of S and O as the group VI elements. Of course, when the first group VI element is, for example, Se belonging to the fourth period, the second group VI element may be O belonging to the second period or S belonging to the third period. In this case, the base material 16 may contain, as the group VI element, two kinds of the group VI elements of Se and S, or Se and O, or may contain three kinds of the group VI elements of Se, S, and O. When the first group VI element is, for example, Te belonging to the fifth period, the second group VI element may be O belonging to the second period, may be S belonging to the third period, and may be Se belonging to the fourth period. In this case, the base material 16 may contain, as the group VI elements, two kinds of the group VI elements of Te and Se, Te and S, or Te and O, or may contain three kinds of the group VI elements of Te, Se and S, Te, Se and O, or Te, S and O. When the first group VI element is, for example, Te belonging to the fifth period, the base material 16 may contain three kinds of the group VI elements of Te, Se, and S, Te, Se, and O, or Te, S, and O, or may contain four kinds of the group VI elements of Te, Se, S, and O.

The second group VI element is not particularly limited as long as it is the group VI element having the period number smaller than the period number of the first group VI element. As described above, the base material 16 may contain the first group VI element and the second group VI element, and may contain three or more kinds of the group VI elements as long as the base material 16 contains two or more kinds of the group VI elements.

The structure of the base material 16 described above need not be observed over the entire area of the EML 8 as long as the structure described above is obtained by observing the EML 8 in the range of about 100 nm in the cross-sectional observation.

When the base material 16 is mixed (doped) with, as impurity elements, different elements that are the same group (that is, the same group in the periodic table) as the constituent elements of the base compound and have a smaller period number than that of the constituent elements, some of the constituent elements of the base compound are substituted with the different elements. In other words, when the different elements each having the same valence electron arrangement as that of the constituent element of the base compound and having a large electronegativity (in other words, having a small ionic radius) indicating ease of electron attraction are mixed into the base material 16, some of the constituent elements are replaced with the different elements.

Thus, when the second group VI elements which are upper than the first group VI elements contained in the base compound by one or more periods are mixed into the base material 16, some of the first group VI elements contained in the base compound are replaced with the second group VI elements. Since the second group VI element has the period number smaller than that of the first group VI element, the second group VI element has a valence electron orbit equivalent to the first group VI element of the base compound and the same number of valence electrons as the first group VI element of the base compound, has an electronegativity larger than the first group VI element, and has an ionic radius smaller than the first group VI element. Thus, even when the second group VI elements are mixed into the base material 16, the base material 16 remains electrically neutral and the conductivity type does not change, but the electronegativity of the second group VI element is larger than that of the first group VI element, and electrons are easily attracted around the second group VI element. As a result, free electrons present in the base compound are bound to the periphery of the added second group VI element, resulting in a spread of the wave function due to uncertainty. Then, an energy level (electron trap level) corresponding to the spread of the wave function and derived from the exciton bound to the second group VI element which is the impurity element appears in the band gap of the base compound. Such an energy level (electron trap level) bound to an impurity atom having the same valence electron arrangement is called an isoelectronic level, an isoelectronic trap, or an isoelectronic band.

As described above, when the base material 16 is doped with the second group VI elements, some of the first group VI elements of the base compound are substituted with the second group VI elements, so that the state of the valence electron is locally changed and the isoelectronic level (isoelectronic band) is formed in the band gap of the base compound.

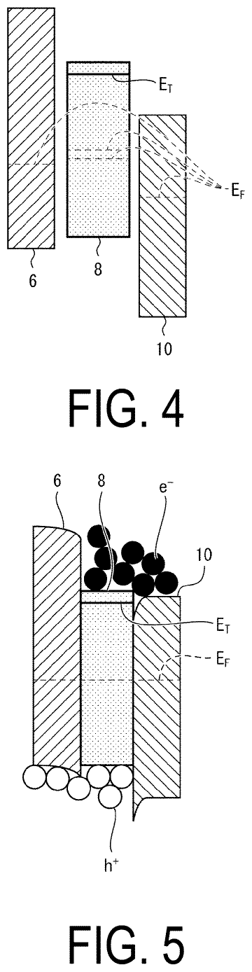

FIG. 4 is a schematic view illustrating an example of a band structure of each function layer when each function layer (HTL 6, EML 8, and ETL 10) between the anode electrode 4 and the cathode electrode 12 is in an isolated state (in other words, each function layer alone) in the light-emitting element 2 illustrated in FIG. 1. FIG. 5 is a schematic view illustrating an example of a band structure of each function layer in a state in which the function layers illustrated in FIG. 4 are bonded to each other and band-shifted so that the Fermi levels coincide with each other. FIG. 4 and FIG. 5 illustrate, as an example, the band structure of each function layer when the base material 16 of the EML 8 containing ZnS as the base compound is doped with O (O doped) as the second group VI element.

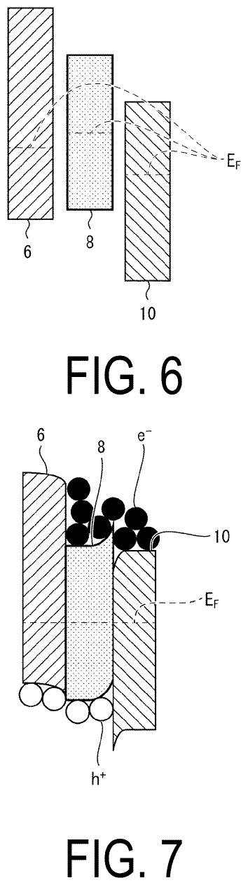

For comparison, FIG. 6 and FIG. 7 illustrate a band structure of each function layer in a light-emitting element for comparison having the same configuration as that of the light-emitting element 2 illustrated in FIG. 1 except that the base material 16 in the EML 8 is not doped with the impurity with respect to the light-emitting element 2 illustrated in FIG. 1. FIG. 6 is a schematic view illustrating an example of a band structure of each function layer when each function layer (HTL 6, EML 8, and ETL 10) between the anode electrode 4 and the cathode electrode 12 is in an isolated state in the light-emitting element for comparison including EML 8′ including the QD 14 and the base material 16 not doped with the impurity element. FIG. 7 is a schematic view illustrating an example of the band structure of each function layer in a state in which the function layers illustrated in FIG. 6 are bonded to each other and band-shifted so that the Fermi levels coincide with each other. That is, in FIG. 5 and FIG. 7, the heights of Fermi levels of function layers are in line with each other for comparing the energy levels. In the following, an effect obtained by the base material 16 containing the second group VI element will be described with reference to an example in which O doping is performed with O being as the second group VI element as described above.

As described above, O is the same group VI element as S of the base compound and is an upper element of S on the periodic table, and thus O has a valence electron orbit equivalent to S of the base compound and the same number of valence electrons as S of the base compound, has an electronegativity larger than S, and has an ionic radius smaller than S. The O substituted for S by doping locally changes the valence electron state, and thus creates an isoelectronic trap level.

The isoelectronic trap level is formed at a position close to a conduction band lower end (CBM) in the band gap of the base compound of the EML 8, and has a state density of at least about a concentration of doped O. Thus, as illustrated in FIG. 4 and FIG. 5, when an isoelectronic trap level ET is formed, the band gap of the EML 8 is equivalently reduced, and there is an effect equivalent to the CBM of the EML 8 becoming effectively deepened. A Fermi level Er is also deeply shifted in accordance with the conduction band level effectively deepened by the O doping. The Fermi level Er is a level at which an existence probability of electrons is ½. The Fermi level Er is in the middle of the band gap for an intrinsic semiconductor. Thus, the Fermi level Er shifts to a position deeper than the band gap of ZnS by ½ of the level effectively deepened by the O doping (in other words, ½ of the amount of reduction of the band gap equivalently reduced by the isoelectronic level ET). O has the same valence as S and a free electron density does not change due to O doping, and thus the base material 16 maintains an intrinsic carrier density, and the Fermi level EF of the EML 8 shifts to the center between an valence band upper end (VBM) of the EML 8 and the isoelectronic level ET of O. The isoelectronic band of O in ZnS has a state density approximately equal to the density of the added O, and thus injected carriers can be transported.

On the other hand, as illustrated in FIG. 6 and FIG. 7, when the O doping is not performed, a Fermi level difference between the EML 8 and the HTL 6 is small and the shift of the junction of each function layer is also small, and thus the hole injection barrier is high.

Thus, as illustrated in FIG. 5, by performing the O doping, the band shift and bending occurring at the junction between the HTL 6 and the mineralized EML 8 become smaller than those of the light-emitting element for comparison illustrated in FIG. 7. Thus, in the light-emitting element 2, as illustrated in FIG. 5, the hole injection barrier to the mineralized EML 8 viewed from the HTL 6 is lower than that of the light-emitting element for comparison illustrated in FIG. 7, and a hole injection efficiency is improved. On the other hand, as illustrated in FIG. 5 and FIG. 7, an electron injection efficiency is the same regardless of whether the O doping is performed.

In the light-emitting element using the QD as the light-emitting material, generally, the injection amount of electrons is greater than the injection amount of holes in the EML, so that there has been a problem of excessive electron supply and shortage of holes. Even when the EML 8 is mineralized by the base material 16, excessive electrons remains unchanged. Thus, by the improvement of the hole injection efficiency, the carrier balance in the mineralized EML 8 is improved and an external quantum efficiency (EQE) is improved.

Thus, as described above, the light-emitting element 2 includes the EML 8 and the HTL 6 provided adjacent to the EML 8, the EML 8 contains the base material 16 containing at least one kind of the inorganic compound and the plurality of QDs 14, the base material 16 contains, as the inorganic compound, the base compound containing at least one kind of the first group VI element as the main component and contains the second group VI element having a smaller periodic number than the first group VI element, and the concentration of the sum of the second group VI elements in the base material 16 is in a range from 1×10¹⁶ atoms/cm³ to 1×10²⁰ atoms/cm³, and thus the carrier balance between holes and electrons can be improved and the light-emitting element 2 having excellent light-emitting characteristics can be provided.

According to the present embodiment, as described above, when the second group VI elements are mixed into the base material 16 such that the concentration of the sum of the second group VI elements in the base material 16 is 1×10¹⁶ atoms/cm³ or more, the second group VI element forms the isoelectronic trap level Er in the band gap of the base compound.

The above concentration is a concentration required for the second group VI element to form the isoelectronic trap level ET. When the second group VI elements are mixed into the base material 16 such that the concentration of the sum of the second group VI elements in the base material 16 is in a range from 1×10¹⁶ atoms/cm³ to 1×10²⁰ atoms/cm³, a valance band upper end of the HTL 6 and a valance band upper end of the EML 8 are close to each other, the hole injection barrier from the HTL 6 to the EML 8 is reduced, and the hole injection efficiency is improved.

However, when the concentration of the sum of the second group VI elements in the base material 16 reaches the composition level of the base compound constituting the base material 16, the valence electron orbital energy of the second group VI element affects interatomic bonds.

For example, when the base compound is ZnS and the second group VI element is O as described above, the energy of the valence electron orbital is O>S in both the p orbital and the s orbital. Thus, when O is at the composition level of the base compound, the band changes in a direction in which the CBM becomes shallower. As a result, the band gap of a base material crystal is widened. In such a situation, the Fermi level EF shifts shallower, and thus an injection layer barrier to the mineralized EML 8 viewed from the HTL 6 is widened, and the hole injection is suppressed.

Thus, the concentration of the sum of the second group VI elements in the base material 16 is required to be in a range of 1×10²⁰ atoms/cm³ or less, which is a concentration less than the composition of the base compound, so as not to exceed a range of a concentration of an impurity level (so-called doping concentration).

As described above, when the second group VI element is O, an upper limit of the O concentration to be less than the composition of the base compound is 1×10²⁰ atoms/cm³ (composition of 0.1%). A lower limit of the concentration at which O forms the isoelectronic trap level ET is 1×10¹⁶ atoms/cm³. Thus, as described above, the second group VI elements are mixed into the base material 16 such that the concentration of the sum of the second group VI elements in the base material 16 is in a range from 1×10¹⁶ atoms/cm³ to 1×10²⁰ atoms/cm³.

The concentration of the sum of the first group VI elements in the base material 16 is desirably 10 times or more higher and more desirably 105 times or more higher than the concentration of the sum of the second group VI elements in the base material 16.

The first group VI elements are contained in the base material 16 at the composition level, and thus the concentration of the sum of the first group VI elements in the base material 16 is at least about 1×10²¹ atoms/cm³. Note that an element contained in the base material 16 at 1×10²¹ atoms/cm³ or more is defined as the main component of the base material 16. In other words, the element contained in the base material 16 at 1×10²¹ atoms/cm³ or more is defined as the main component of the base compound. The main component is not limited to one kind of element. The base material 16 may contain two or more kinds of the first group VI elements as the main components. The base material 16 may contain the group II element as the main component. The group II element may be one of the main components or need not be the main component. The base material 16 may also contain elements other than the first group VI element and the second group VI element at a compositional level in a range from larger than 1×10²⁰ atoms/cm³ to less than 1×10²¹ atoms/cm³. The base material 16 may contain, as an element other than the main component, for example, the group II element, and may contain a halogen element or an element such as Li used in a mixed crystal.

On the other hand, the concentration of the sum of the second group VI elements in the base material 16 is at most 1×10²⁰ atoms/cm³, and thus the concentration of the sum of the first group VI elements in the base material 16 is 10 times or more higher than the concentration of the sum of the second group VI elements in the base material 16. The concentration of the sum of the second group VI elements in the base material 16 is the impurity concentration as described above and has a lower limit of 1×10¹⁶ atoms/cm³ in consideration of the detection limit, and thus the concentration of the sum of the first group VI elements in the base material 16 is more desirably 105 times or more higher than the concentration of the sum of the second group VI elements in the base material 16.

As described above, the fact that O is doped into the base material 16 as the impurity and O is taken into the crystal of the base compound can be determined from a chemical shift of O by element concentration analysis using an electron probe microanalyzer (EPMA). As described above, the fact that the second group VI element is doped as the impurity in the base material 16 can be determined by EPMA.

The concentration of the sum of the second group VI elements in the base material 16 can be measured by secondary ion mass spectrometry (SIMS). The above concentration can also be measured by Auger electron spectroscopy (AES). An lower limit of a detection accuracy is SIMS (ppm)<AES (%), and the detection accuracy of SIMS is 10000 times higher than that of AES. An lower limit of a spatial resolution is AES (30 nm)<SIMS (200 nm). Although the spatial resolution of SIMS is 6.7 times lower than that of AES, SIMS can also perform analysis on a scale sufficiently smaller than one pixel. Thus, although AES can be used for the measurement of the concentration, SIMS having high detection accuracy is more preferably used.

In the present embodiment, the organic ligand is removed by mineralization, and thus it can be determined that the second group VI element detected by SIMS, EPMA, or the like is not derived from an organic matter but added into the base material 16.

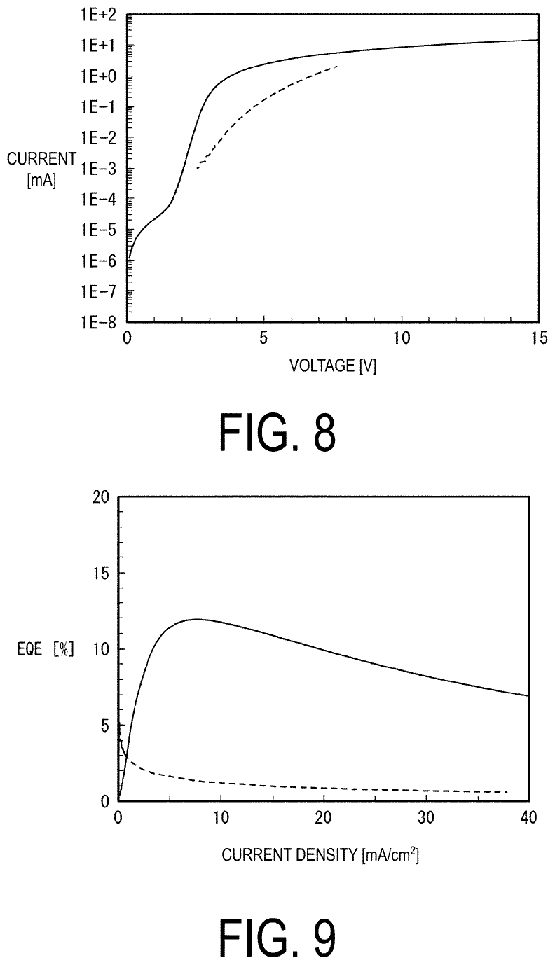

FIG. 8 is a graph showing J-V characteristics of the light-emitting element 2 according to the present embodiment in which the O doping is performed on the base material 16 containing ZnS as the base compound and J-V characteristics of the light-emitting element for comparison in which the O doping is not performed on the base material 16 containing ZnS as the base compound.

In FIG. 8, a solid line indicates, as the J-V characteristic, a relationship between a voltage applied to the light-emitting element 2 and a current flowing through the light-emitting element 2 via junctions of the HTL 6, EML 8, and ETL 10 as indicated by I in FIG. 1. A broken line indicates, as the J-V characteristic, a relationship between a voltage applied to the light-emitting element for comparison and a current flowing through the light-emitting element for comparison via junctions of the HTL 6, EML 8, and ETL 10 in the light-emitting element for comparison.

It can be seen from FIG. 8 that by performing the O doping on the base material 16, a rising voltage of the current of the light-emitting element 2 decreases by about 1 V as compared with a rising voltage of the current of the light-emitting element for comparison, and a slope changes toward steeper.

In general, as the radiative recombination of the injected carriers more efficiently occurs, a current flowing through the light-emitting element exhibits a steep slope. As described above, the current I flowing through the light-emitting element 2 via the junction of the HTL 6, the EML 8, and the ETL 10 contributes to the radiative recombination of the carriers.

Thus, from the results shown in FIG. 8, it can be presumed that by performing the O doping on the base material 160, the carriers are efficiently injected into the mineralized EML 8, and the radiative recombination of the injected carriers are improved.

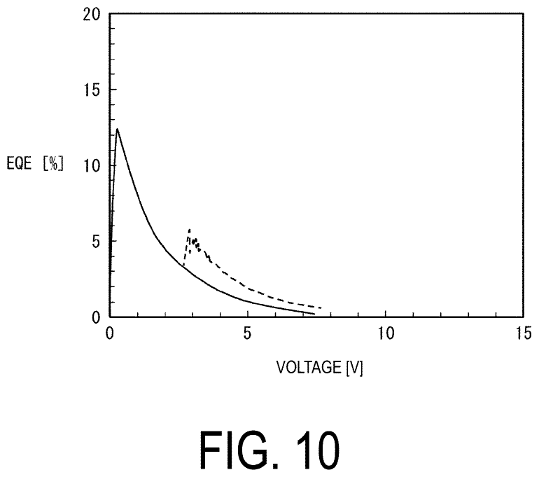

FIG. 9 and FIG. 10 are graphs each showing emission characteristics of the light-emitting element 2 according to the present embodiment in which the O doping is performed on the base material 16 containing ZnS as the base compound and emission characteristics of the light-emitting element for comparison in which the O doping is not performed on the base material 16 containing ZnS as the base compound.

In FIG. 9, a solid line indicates a relationship between a current density applied to the light-emitting element 2 and the external quantum efficiency (EQE) as the light emission characteristics, and a broken line indicates a relationship between a current density applied to the light-emitting element for comparison and the EQE as the light emission characteristics. In FIG. 10, a solid line indicates a relationship between a voltage applied to the light-emitting element 2 and the EQE as the light emission characteristics, and a broken line indicates a relationship between a voltage applied to the light-emitting element for comparison and the EQE as the light emission characteristics.

In the EQE with respect to the current density, as shown in FIG. 9, the maximum value (peak EQE) of the EQE of the light-emitting element for comparison is about 5%, whereas the peak EQE of the light-emitting element 2 is about 12%, and the EQE is greatly improved by performing the O doping on the base material 16. This light emission characteristic coincides with a prediction from the J-V characteristic shown in FIG. 8. The current density exhibiting the peak EQE is 1 mA/cm² or less in the light-emitting element for comparison, whereas the current density is shifted to the vicinity of 10 mA/cm² in the light-emitting element 2, which indicates that carriers can be injected into a level corresponding to the radiative recombination rate of the QD 14 contained in the mineralized EML 8. The above results indicate that almost all the current flowing through the light-emitting element 2 is injected into the EML 8 without waste and contributes to light emission.

In addition, as shown in FIG. 10, in the EQE with respect to the voltage, the voltage exhibiting the peak EQE of the light-emitting element 2 is shifted to the low voltage side by about 2 V as compared with the light-emitting element for comparison, which indicates that the injection loss of carriers can be significantly reduced.

The base material 16 may further contain at least one kind of a halogen element. For example, as illustrated in FIG. 2, the base material 16 may include halide ions 16H each having at least one of a fluoride ion, a chloride ion, a bromide ion, and an iodide ion.

The halogen element is bonded to an unpaired electron of the base compound to be stabilized, and thus a defect of the base material 16 can be inactivated. Here, “a defect of the base material 16 can be inactivated” means that the unpaired electron is used for bonding with the halogen element, and thus the defect does not function as a non-luminescent center or a carrier trap. As illustrated in FIG. 2, when the halide ions 16H are present in the vicinity of a surface of the QD 14, dispersibility of the QD 14 is improved. Thus, the base material 16 desirably contains the halogen element. A range of about a thickness of the shell 14S may be the vicinity of the surface of the QD 14.

The base material 16 may contain 1 atomic % or more of the halogen element. The concentration of the sum of the halogen elements in the base material 16 is desirably 1×10¹⁶ atoms/cm³ or more. The concentration of the sum of the halogen elements in the base material 16 is desirably 1×10¹⁹ atoms/cm³ or less.

The halogen element may be contained in the base material 16 to such an extent as to fill the defect of the base material 16. The concentration of the sum of the halogen elements in the base material 16 is sufficient at much lower concentration than the composition of the base material 16, and when the concentration of the sum of the halogen elements in the base material 16 reaches the composition level of the base material 16, the properties of the base material 16 may change. When the halogen elements which are not incorporated into the composition of the base material 16 are present at a high density, there is a high possibility that the quality of the base material 16 is significantly deteriorated.

Thus, considering that, (i) the concentration of the sum of the halogen elements in the base material 16 needs to be set lower than the composition level of the base material 16 as described above, (ii) a surface defect density of heteroepitaxially grown GaN/sapphire having a high defect density is 1×10⁹/cm² or more, (iii) a temperature for synthesizing the base material 16 is considerably lower than a general semiconductor growth temperature, (iv) a II-VI compound susceptible to group IV defects is used as the base compound, and (v) a defect surface density in the base material 16 is estimated to be on the order of at least 1×10¹⁰/cm², the concentration of the sum of the halogen elements in the base material 16 is desirably 1×10¹⁶ atoms/cm³ or more and 1×10¹⁹ atoms/cm³ or less as a value that sufficiently inactivates the defect and can be detected.

It is preferable that a concentration of the halide ion 16H in the vicinity of each QD 14 in the EML 8 is higher than a concentration of the halide ion 16H on the peripheral side than the vicinity of each QD 14. For example, in the periphery of a certain QD 14, a range whose distance from the outermost surface of the QD 14 is within 1 nm may be defined as the vicinity of the QD 14.

Thus, for example, as illustrated in FIG. 2, in the periphery of the QD 14, the mean value of the concentrations of the sum of halogen atoms within a distance DA of 1 nm or less from the outer surface of the shell 14S which is the outermost surface of the QD 14 may be higher than the mean value of the concentrations of the sum of the halogen atoms in the other positions. In this case, the mean value of the concentrations of the sum of the halogen atoms within the distance DA of 1 nm may be 10% or more, 50% or more, or 100% or more higher than the mean value of the concentrations of the sum of the halogen atoms at the other positions. Such a concentration distribution can be confirmed by, for example, element mapping by cross-sectional transmission electron microscope-energy dispersive X-ray spectroscopy (TEM-EDX).

Here, the “other positions” can also be said to be positions where no QD 14 exists within 1 nm. The plurality of QDs 14 are included in the EML 8. Thus, it can be said that the above value is a value obtained by comparing the mean value of the concentrations of the sum of the halogen atoms in a range of the surrounding 1 nm of each of the QDs 14 in the EML 8 with the mean value of the concentrations of the sum of the halogen atoms in the portion away from any QD 14 in the EML 8 beyond 1 nm.

That is, the mean value of the concentrations of the sum of the halogen elements in the region within 1 nm from the outermost surface of each of the plurality of QDs 14 in the base material 16 is preferably higher than the mean value of the concentrations of the sum of the halogen elements in the region at a distance exceeding 1 nm from the outermost surface of each of the plurality of QDs 14 in the base material 16, and may be, for example, 10% or more, 50% or more, or 100% or more higher.

In this way, the dispersibility of the QD 14 can be further improved, and the EML 8 having a more uniform thickness can be formed.

The base material 16 can contain the halide ions by forming the EML 8 by using a QD dispersion containing the halogen element and the QD 14.

### Manufacturing Method for Light-Emitting Element 2

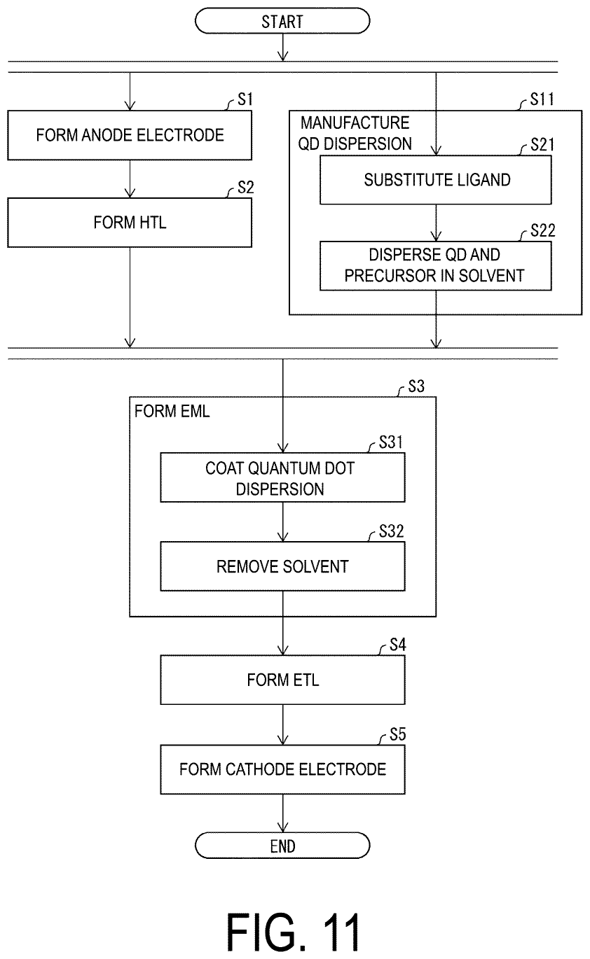

Next, a manufacturing method for the light-emitting element 2 according to the present embodiment will be described with reference to FIG. 11. FIG. 11 is a flowchart illustrating an example of the manufacturing method for the light-emitting element 2 according to the present embodiment.

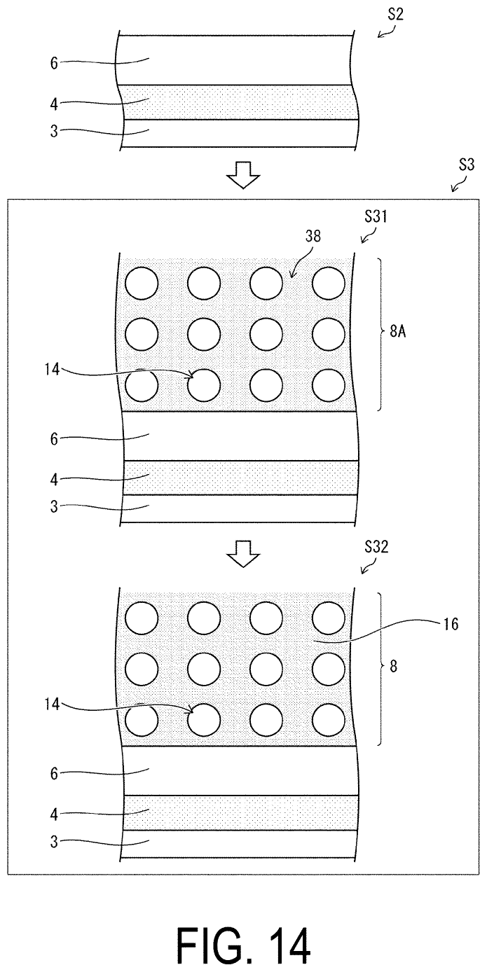

As illustrated in FIG. 11, in the manufacturing method for the light-emitting element 2 according to the present embodiment, first, the anode electrode 4 is formed on a substrate 3 as a support body as illustrated in FIG. 14 described later (step S1: anode electrode forming step). Subsequently, the HTL 6 is formed (step S2: HTL forming step). In parallel, the QD dispersion is manufactured (prepared) (step S11: QD dispersion manufacturing step). Subsequently, the EML 8 is formed using the QD dispersion (step S3: EML forming step). Subsequently, the ETL 10 is formed (step S4: ETL forming step). Subsequently, the cathode electrode 12 is formed (step S5, cathode electrode forming step). In this way, the light-emitting element 2 is manufactured.

For the formation of the anode electrode 4 in step S1 and the formation of the cathode electrode 12 in step S5, for example, a vapor deposition method or a sputtering method is used.

For the formation of the HTL 6 in step S2 and the formation of the ETL 10 in step S4, for example, a vacuum vapor deposition technique, a sputtering technique, a coating technique using colloidal solution, or a sol-gel technique is used.

Here, before describing step S3, step S11 will be described in more detail.

### Step S11

QD dispersion preparation step of step S11 includes a ligand substitution step (step S21) of substituting a ligand coordinated with the QD 14.

As a ligand, an organic ligand is often coordinated with a synthetic or commercially obtained QD. A commercially available QD is generally provided in the form of a QD dispersion that contains an organic ligand. The organic ligand is used as a dispersant to improve the dispersibility of the QD in a QD dispersion, and is also used to improve the surface stability and storage stability of the QD. For example, a wet method is used for synthesis of the QD, and particle size control of the QD is performed by coordinating an organic ligand to the surface of the QD. Therefore, the QD dispersion synthesized by the wet method includes the organic ligand used for the synthesis of the QD. Thus, in the present embodiment, in order to mineralize the EML 8, the ligand substitution step of substituting the ligand coordinated with the QD 14 is performed.

In the present embodiment, for example, a QD dispersion containing the QD with which the halide ion is coordinated is used as the QD dispersion. Thus, in the ligand substitution step, the halide ion is coordinated with the QD 14 by substituting the organic ligand with the halide ion.

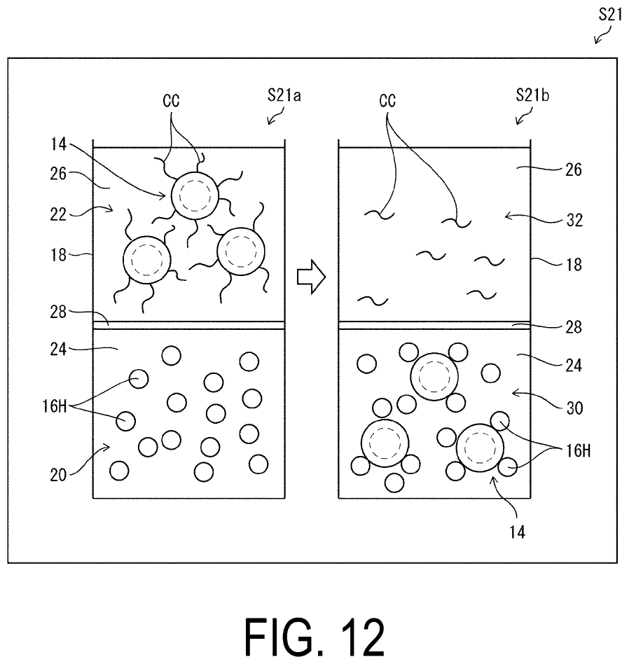

Hereinafter, a method of substituting the organic ligand coordinated with the QD 14 with the halide ion 16H will be described with reference to FIG. 12.

FIG. 12 is a schematic cross-sectional view for describing a ligand substitution step (step S21) illustrated in FIG. 11. As illustrated in FIG. 12, in the ligand substitution step, first, a first solution 20 in which the halide ion 16H is dissolved and a second solution 22 in which the QDs 14 with which carbon chains CC as organic ligands are coordinated are dispersed are injected into a container 18 (step S21a). The first solution 20 includes a first solvent 24 in which the halide ion 16H is soluble, and the second solution 22 includes a second solvent 26 in which the carbon chain CC is soluble. For example, the second solvent 26 has a polarity different from that of a first solvent 24 and has a specific gravity lower than that of the first solvent 24. In order to more clearly distinguish a boundary between the first solution 20 and the second solution 22, a separation liquid 28 having a specific gravity and polarity between those of the first solvent 24 and the second solvent 26 may be injected into the container 18.

The first solvent 24 may include, for example, at least one kind of an organic solvent selected from the group consisting of dimethyl sulfoxide (DMSO), N,N-dimethylformamide (DMF), N-methylformamide (NMF), formamide, N,N′-dimethylpropyleneurea, dimethylacetamide, N-methylpyrrolidone, gamma-butyrolactone, propylene carbonate, acetonitrile, 2-methoxyethanol, methyl acetate, ethyl acetate, ethyl formate, methyl formate, tetrahydrofuran, diethyl ether, tetrahydrothiophene, and diethyl sulfide. In this case, the first solvent 24 well disperses both the QD 14 with which the halide ion 16H is coordinated and a precursor of the base material 16. The first solvent 24 may be a polar solvent having a polarity larger than that of the second solvent 26. The first solvent 24 may be prepared, for example, by dispersing zinc chloride, sodium chloride, or hydrochloric acid, in NMF, DMF, or DMSO. The second solvent 26 is desirably, for example, toluene, hexane, octane, octadecene, or the like. The second solvent 26 is desirably a non-polar solvent that is immiscible with the first solvent 24.

The carbon chain CC may be a carbon chain to be generally used as the ligand of the QD. The second solvent 26 is a solvent in which the carbon chains CC are soluble, and thus the QD 14 with which the carbon chain CC is coordinated is easily dispersed in the second solution 22. The halide ion 16H is dissolved in the first solution 20 in an excessive amount exceeding the amount of the halide ion 16H capable of being coordinated with the QD 14. A concentration of the halide ion 16H in the first solvent 24 is desirably 0.01 mol/L or more, and more desirably 0.1 mol/L or more.

Subsequently, the container 18 containing the first solution 20 and the second solution 22 described above is vibrated at a high speed by a stirrer to stir the first solution 20 and the second solution 22 (step S21b). To improve stirring efficiency, a stirring bar may be put into the container 18. In other words, the step of stirring the first solution 20 and the second solution 22 is a step of processing the QD 14 with the halide ion 16H, and is, in particular, a step of generating the QD 14 with which the halide ion 16H is coordinated.

Here, as described above, the first solution 20 contains an excessive amount of the halide ion 16H. In general, when two or more kinds of ligands are contained in a solution in which the QDs are dispersed, the ligands to be coordinated with the QDs are in an equilibrium state between the ligands in the solution. Thus, when the first solution 20 and the second solution 22 are stirred, at least some of the ligands coordinated with the QDs 14 are substituted from the carbon chains CC to the halide ions 16H.

For example, in step S21b, the solutions in the container 18 are stirred for at least one minute or longer. The stirring of the solutions in the container 18 may be performed at a frequency of 10 times per minute for 1 hour with the temperature of the solutions in the container 18 set to 25° C. Under such conditions, it can be said that the probability that the ligands coordinated with the QDs 14 in the container 18 are replaced by the halide ions 16H is sufficiently high. In addition, to prevent water, oxygen, or the like in the air from being mixed with the solutions in the container 18, it is more desirable that the solutions in the container 18 are stirred in an atmosphere of nitrogen, argon, or the like.

Accordingly, by the stirring, as illustrated in step S21b of FIG. 12, a third solution 30 in which the QDs 14 with which the halide ions 16H are coordinated are dispersed in the first solvent 24 and a fourth solution 32 in which the carbon chains CC are dissolved in the second solvent 26 are obtained in the container 18. As described above, the QDs 14 with which the halide ions 16H are coordinated are obtained in the third solution 30. Note that the stirring may be completed when the liquid in the container 18 is irradiated with ultraviolet light or the like and it is confirmed that the liquid layer emitting light moves from the upper side to the lower side of the container 18.

Subsequently, a QD dispersion step (step S22) is performed in which the QDs 14 with which the halide ions 16H are coordinated and the precursors of the base material 16 are dispersed in a solvent. In this way, the QD dispersion containing the QDs 14 with which the halide ions 16H are coordinated, the precursors of the base material 16, and the solvent which are used to form the EML 8 in step S3, is manufactured.

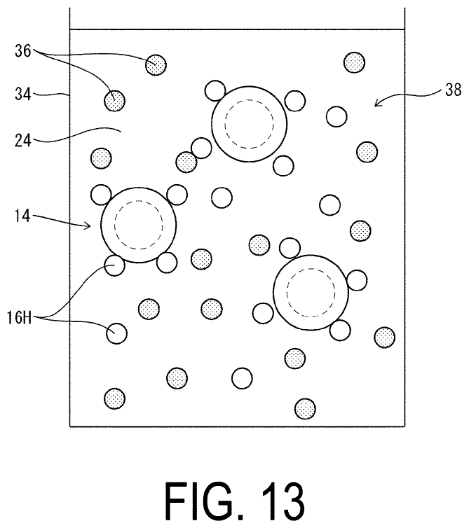

FIG. 13 is a cross-sectional view illustrating a schematic configuration of a QD dispersion 38 used for forming the light-emitting element 2 according to the present embodiment manufactured in step S22.

In step S22, for example, after step S21, subsequently only the third solution 30 is extracted from the container 18 by a dropper or the like. Then, the extracted third solution 30 and a precursor solution in which precursors 36 which are precursors of the base material 16 are dispersed in, for example, the first solvent 24 are mixed in a container 34 illustrated in FIG. 13. In this way, as illustrated in FIG. 13, the QDs 14 with which the halide ions 16H are coordinated and the precursors 36 are dispersed in, for example, the first solvent 24 to manufacture (prepare) the QD dispersion 38 containing the QDs 14, the precursors 36, and the first solvent 24.

The precursor solution may be previously injected into the container 18 before the third solution 30 is injected, or the precursor solution may be injected into the container 18 after the injection of the third solution 30 or simultaneously with the injection of the third solution 30. The order of addition (injection) of the third solution 30 and the precursor solution is not particularly limited.

The precursor 36 contains the first group VI element. When the first group VI element is S and the base compound is a metal sulfide such as ZnS as described above, the precursor 36 may contain, as a group II element source containing the group II element, at least one metal source containing the group II element as the metal element and selected from the group consisting of, for example, a metal acetate, a metal nitrate, and a metal halide.

In this case, the precursor 36 may contain, as the first group VI element source containing the first group VI element, at least one sulfur source containing sulfur as the first group VI element and selected from the group consisting of thiourea, N-methylthiourea, 1,3-dimethylthiourea, N,N′-dimethylthiourea, tetramethylthiourea, and thioacetamide.

In addition, the precursor 36 may contain a metal complex in which thiourea, N-methylthiourea, 1,3-dimethylthiourea, N,N′-dimethylthiourea, tetramethylthiourea, or thioacetamide is coordinated with a metal element (for example, a metal atom).

The second group VI element may be contained in the precursor 36, may be contained in, for example, the first solvent 24 in which the precursors 36 are dispersed, or may be added after the third solution 30 and the precursor solution are mixed. A method of mixing (doping) the second group VI element into the base material 16 is not particularly limited.

When the base material 16 contains O as the second group VI element, examples of a method of mixing O into the base material 16 include, as an example, a method of adjusting the pH of the QD dispersion 38 so that the pH of the QD dispersion 38 is slightly acidic of about pH 6.5. An acid may be added to adjust the pH of the QD dispersion 38. By adding a small amount of acid to slightly lower the pH and to slightly increase the OH concentration, a small amount of O can be mixed into the base material 16.

A required amount of acid used for pH adjustment can be determined by the following equation (1). The following equation (1)

$$Z = ( N \times n \times Q \times {10}^{5} ) / ( 60 \times W \times D ) \qquad ( 1 )$$

may be used to obtain the PH by taking the common logarithm of n (H⁺ concentration) in the equation (1).

In the equation (1), Z represents the required amount (mL) of the acid. N represents 1 gram equivalent (g) of the acid. n represents a target H⁺ concentration (mol/L). Q represents a solvent total amount (m³). For example, when the first solvent 24 is used as the solvent as described above, Q represents a total amount of the first solvent 24. W represents a concentration (wt %) of the acid. D represents the specific gravity of the acid.

Examples of the acid include hydrochloric acid (HCl), sulfuric acid (H₂SO₄), and phosphoric acid (H₃PO₄). Among these acids, HCl which does not contain P, S, or the like is preferably used. HCl is composed only of the elements contained in the precursor 36 and the first solvent 24 for mineralization, and thus there is no contamination of foreign elements into the base material 16.

By adding the acid as described above, the pH of the first solvent 24 which is a solvent changes, and the pH of the QD dispersion 38 changes. When the pH of the QD dispersion 38 changes, a reaction of the precursor 36 also changes. Thus, when the pH of the QD dispersion 38 is adjusted by lowering the pH of the QD dispersion 38 with the acid as described above, it is desirable to change the reaction temperature depending on the pH, for example, or to lengthen the reaction time when the reaction temperature is not changed. In this way, the layer thickness of the mineralized EML 8 can be kept constant.

When the base material 16 contains a group VI element other than O as the second group VI element, in order to mix the second group VI element other than O into the base material 16, for example, the precursor 36 containing a second group VI element source at the above-described impurity concentration may be used. By dispersing, as the compound containing the second group VI element, a compound of the same group II element as the group II element source contained in the precursor 36 together with the precursor 36 in the first solvent 24, the QD dispersion 38 may be prepared to contain the plurality of QDs 14, the precursors 36 containing the first group VI elements, the compound containing the second group VI element, and the first solvent 24 such that the concentration of the second group VI element in the base material 16 is in a range from 1×10¹⁶ atoms/cm³ to 1×10²⁰ atoms/cm³.

Next, step S3 will be described in greater detail.

### Step S3

FIG. 14 is a cross-sectional view of steps illustrating an example of a method of forming the EML 8.

As illustrated by S2 in FIG. 14, at the time of completion of step S2, the substrate 3, the anode electrode 4, and the HTL 6 are formed.

In step S3, first, the QD dispersion 38 manufactured in step S11 is coated onto the HTL 6. In this way, a coating layer 8A containing the QD dispersion 38 is formed as a coating film on the HTL 6 (step S31, QD dispersion coating step).

As a method of forming the coating film, any method such as, for example, a bar coating method, a spin coating method, or an ink-jet method can be appropriately selected. Subsequently, the first solvent 24 contained in the coating layer 8A is removed by baking (heating) or the like the coating layer 8A to dry the coating layer 8A (step S32: solvent removal step).

As an example, in step S32, for example, after step S31, a layered body from the substrate 3 to the coating layer 8A is heated at a temperature from 80° C. to 500° C. for 1 minute or longer to dry the coating layer 8A. As the coating layer 8A is dried, the precursor 36 is denatured (crystallized). In this way, the base material 16 is formed which contains the base compound containing at least one kind of the first group VI element as the main component and contains at least one kind of the second group VI element at the concentration of the above-described impurity level (so-called doping concentration) with respect to the base material 16. In this way, the EML 8 containing the base material 16 containing the first group VI element and the second group VI element and the QD 14 is formed on the HTL 6.

The concentration of the second group VI element in the EML 8 mineralized by such a procedure can be determined by, for example, SIMS or the like as described above. For example, the EML 8 containing ZnS as the base compound and O as the second group VI element was formed using zinc acetate (ZnC₄H₆O₄) as the metal source for the precursor 36, thiourea (CH₄N₂S) for the sulfur source, dimethylsulfoxide for the first solvent 24, and HCl for the acid to adjust the pH of the QD dispersion 38 to, for example, pH 6.5. The concentration of O contained in the obtained EML 8 was measured by SIMS and found to be 1×10¹⁶ atoms/cm³. The fact that O as the second group VI element is doped as the impurity can be determined by evaluating the chemical shift of O by EPMA. The organic ligand is removed by mineralization, and thus it can be determined that O detected by SIMS and EPMA is not derived from an organic matter but added into the base material 16.

The concentration of O is the concentration of the impurity level (so-called doping concentration) with respect to the base material 16, and does not reach the composition of the base compound. The concentration of O is equal to or more than a concentration required for O to form the isoelectronic trap level ET.

Thus, in this case, O forms the isoelectronic trap level Er in the band gap of ZnS which is the base compound. As a result, as described above, the CBM of the HTL 6 and the CBM of the EML 8 were brought close to each other, the hole injection barrier from the HTL 6 to the EML 8 was reduced, and the hole injection efficiency was improved. As a result, the carrier balance between holes and electrons was improved, and as shown in FIG. 8 to FIG. 10, the light-emitting element 2 having excellent light-emitting characteristics could be obtained.

As described above, when the halide ion 16H is coordinated with the shell 14S of the QD 14, the dispersibility of the QD 14 with respect to the polar solvent is high, and precipitation of the QD 14 hardly occurs. In addition, when the halide ion 16H is coordinated with the shell 14S of the QD 14, the aggregation of the QD 14 caused by the reaction of the precursor 36 on the surface of the QD 14 is suppressed, and the dispersibility of the QD 14 can be maintained for a long period of time.

Furthermore, when the drying of the first solvent 24 of the QD dispersion 38 proceeds from step S31 to step S32, the concentration of the QD 14 in the QD dispersion 38 increases. However, when the halide ion 16H is coordinated with the shell 14S of the QD 14 as described above, the QD 14 can be suppressed from precipitating before the precursor 36 is deposited on the HTL 6. Thus, when the halide ion 16H is coordinated with the shell 14S of the QD 14, the EML 8 which is smoother and in which the QD 14 is more uniformly dispersed can be formed.

As described above, in step S32, to form the EML 8, the layered body from the substrate 3 to the coating layer 8A is heated to, for example, 80° C. to 500° C. Thus, all the layers from the anode electrode 4 to the coating layer 8A are preferably formed of layers made of inorganic materials. All the layers from the anode electrode 4 to the cathode electrode 12 are more preferably formed of layers made of the inorganic materials.

### Modified Example

FIG. 1 illustrates an example in which the anode electrode 4 is a lower layer electrode, the cathode electrode 12 is an upper layer electrode, and the EML 8 is provided on the HTL 6. However, the disclosure is not limited thereto.

In the light-emitting element 2, the cathode electrode 12 may be the lower layer electrode, the anode electrode 4 may be the upper layer electrode, and the HTL 6 may be provided above the EML 8. Thus, the light-emitting element 2 may have a configuration in which, for example, the cathode electrode 12, the ETL 10, the EML 8, the HTL 6, and the anode electrode 4 are provided in this order from the lower layer side (e.g., a support body side not illustrated such as the substrate 3).

In this case, the layering order of the light-emitting element 2 is reversed from the light-emitting element 2 illustrated in FIG. 1. Thus, when such a light-emitting element 2 is manufactured, first, the cathode electrode 12 is formed on the substrate 3 as the support body (step S5: cathode electrode forming step). Subsequently, the ETL 10 is formed (step S4: ETL forming step). In parallel, the QD dispersion is manufactured (prepared) (step S11: QD dispersion manufacturing step). Subsequently, the EML 8 is formed using the QD dispersion (step S3: EML forming step). Subsequently, the HTL 6 is formed (step S2: HTL forming step). Subsequently, the anode electrode 4 is formed (step S1, anode electrode forming step). In this way, the light-emitting element 2 is manufactured.

Also in this case, the light-emitting element 2 may include the function layer not illustrated other than the HTL 6, the EML 8, and the ETL 10 between the anode electrode 4 and the cathode electrode 12.

### Second Embodiment

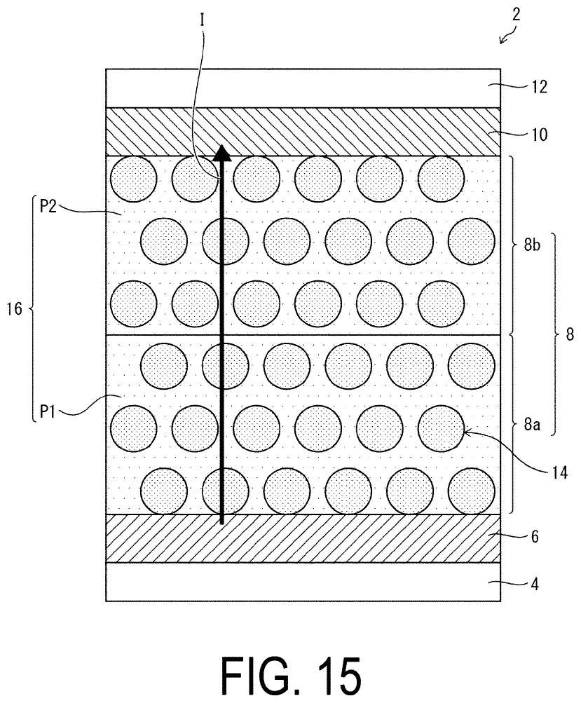

Overall Configuration of Light-Emitting Element 2 FIG. 15 is a cross-sectional view illustrating a schematic configuration of a light-emitting element 2 according to the present embodiment.

As illustrated in FIG. 15, the light-emitting element 2 includes the ETL 10 provided adjacent to the EML 8 on an opposite side of the HTL 6 across the EML 8.

In the light-emitting element 2 according to the present embodiment, the concentration of the sum of the second group VI elements in the base material 16 on a side closer to the HTL 6 than a center of the EML 8 in the thickness direction is higher than the concentration of the sum of the second group VI elements in the base material 16 on a side closer to the electron transport layer than the center of the EML 8 in the thickness direction. Thus, in the EML 8 of the light-emitting element 2 according to the present embodiment, the base material 16 includes a first portion P1 having a relatively high concentration of the sum of the second group VI elements and a second portion P2 having a relatively low concentration of the sum of the second group VI elements.

For example, as illustrated in FIG. 15, the EML 8 may have a configuration in which a first EML 8a in which the concentration of the sum of the second group VI elements in the base material 16 is relatively high and a second EML 8b in which the concentration of the sum of the second group VI elements in the base material 16 is relatively low are layered.

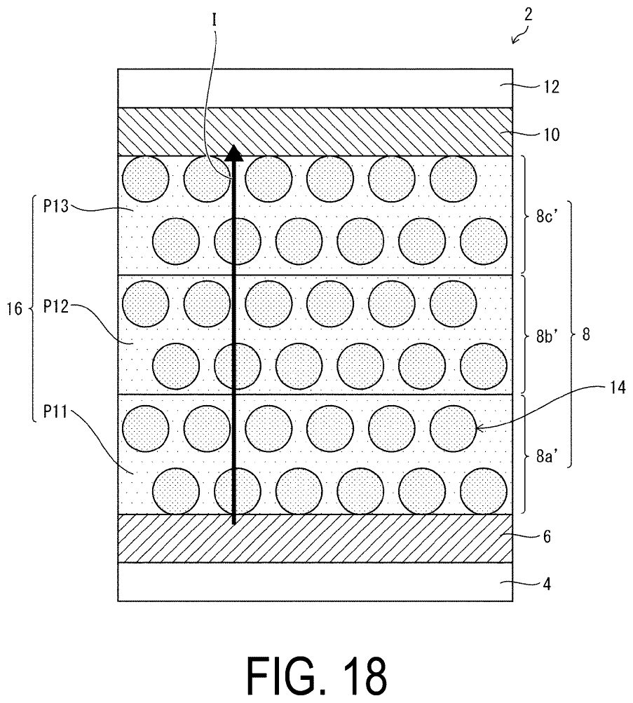

For example, the EML 8 may include the first EML 8a adjacent to the HTL 6, and the second EML 8b provided to be adjacent to each of the first EML 8a and the ETL 10 between the first EML 8a and the ETL 10. In this case, the base material 16 of the first EML 8a is the first portion P1, and the base material 16 of the second EML 8b is the second portion P2. However, the embodiment is not limited thereto. For example, as illustrated in FIG. 18 described later, an intermediate layer may be provided between the first EML 8a and the second EML 8b.

The light-emitting element 2 illustrated in FIG. 15 has, as an example, a configuration in which the anode electrode 4, the HTL 6, the EML 8 including the first EML 8a and the second EML 8b provided on the first EML 8a, ETL 10, and the cathode electrode 12 are provided in this order from the lower layer side (e.g., a side of a support body not illustrated such as the substrate 3).

The first EML 8a and the second EML 8b have the same layer thickness, and have the same configuration except that the concentrations of the sum of the second group VI elements in the base material 16 are different from each other as described above. The total layer thickness of the layer thickness of the first EML 8a and the layer thickness of the second EML 8b may be larger than the layer thickness of the EML 8 according to the first embodiment, but is desirably the same as the layer thickness of the EML 8 according to the first embodiment. The layer thickness of the EML 8 is designed such that a light extraction efficiency is optimal. Thus, even when the EML 8 is divided into the first EML 8a and the second EML 8b, the highest luminous efficiency can be obtained by not changing the layer thickness of the entire EML 8 from the optimum layer thickness.

The sum of the concentrations of the second group VI element in the base material 16 on the side closer to the HTL 6 than the center of the EML 8 in the thickness direction may be in a range from 1×10¹⁹ atoms/cm³ to 1×10²⁰ atoms/cm³. Thus, the sum of the concentrations of the second group VI element in the first portion P1 of the first EML 8a may be in a range from 1×10¹⁹ atoms/cm³ to 1×10²⁰ atoms/cm³.

The sum of the concentrations of the second group VI element in the base material 16 on the side closer to the ETL 10 than the center of the EML 8 in the thickness direction may be in a range from 1×10¹⁶ atoms/cm³ to 1×10¹⁸ atoms/cm³. Thus, the sum of concentrations of the second group VI element in the second portion P2 of the second EML 8b may be in a range from 1×10¹⁹ atoms/cm³ to 1×10²⁰ atoms/cm³. However, as described above, it is premised that the condition of (the sum of the concentrations of the second group VI element in the first portion P1)> (the sum of the concentrations of the second group VI element in the second portion P2 in the second EML 8b) is satisfied.

However, the present embodiment is not limited to this. The second group VI element may be mixed only into the base material 16 on the side closer to the HTL 6 than the center of the EML 8 in the thickness direction. Thus, the second group VI element may be mixed only into the second EML 8b among the first EML 8a and the second EML 8b, or the second group VI element may be mixed only into the first portion P1 among the first portion P1 and the second portion P2.

In this case, the second group VI element may be mixed over ½ of the thickness of the EML 8.

In any case, as described above, when the concentration of the second group VI element is relatively high on the side closer to the HTL 6 than the center of the EML 8 in the thickness direction, the hole injection efficiency can be improved and the EQE can be further improved.

When the concentration of the sum of the second group VI elements on the side closer to the HTL 6 is relatively high as described above, the second group VI element diffuses from the EML 8 to the HTL 6 with the lapse of time. For example, when the second group VI element is O as described above, diffusion of O from the EML 8 to the HTL 6 occurs with the lapse of time to suppress an oxygen deficiency of the HTL 6. When the above-described HIL is provided between the HTL 6 and the anode electrode 4, O diffused from the EML 8 to the HTL 6 is diffused to the HIL with the lapse of time to suppress an oxygen deficiency of the HTL 6 and the HIL. In particular, in the HIL made of an inorganic material, the oxygen deficiency becomes a source of free electrons. Thus, when the oxygen deficiency is suppressed, hindrance of hole transport due to the oxygen deficiency can be suppressed. This makes it possible to provide the light-emitting element 2 having high reliability.

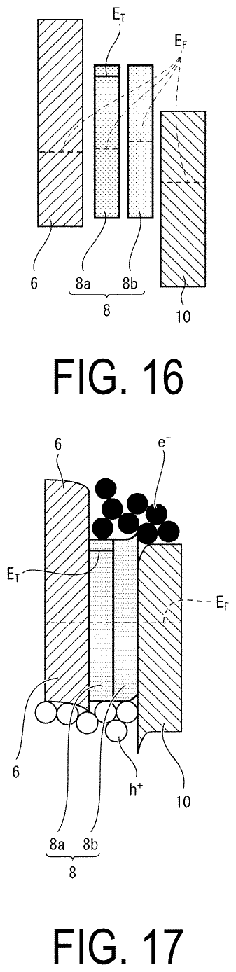

FIG. 16 is a schematic view illustrating an example of a band structure of each function layer when the second group VI element is mixed only into the first portion P1 of a first EML 8a and each function layer (the HTL 6, the first EML 8a, the second EML 8b, and the ETL 10) between the anode electrode 4 and the cathode electrode 12 is in an isolated state in the light-emitting element 2 illustrated in FIG. 15. FIG. 17 is a schematic view illustrating an example of the band structure of each function layer in a state in which the function layers illustrated in FIG. 16 are bonded to each other and band-shifted so that the Fermi levels coincide with each other. FIG. 16 and FIG. 17 also illustrate, as an example, the band structure of each function layer when only the first portion P1 in the base material 16 of the EML 8 containing ZnS as the base compound is doped with O (O doped) as the second group VI element.

As illustrated in FIG. 15 and FIG. 16, in the light-emitting element 2 according to the present embodiment, the concentration of O in the first EML 8a is higher than the concentration of O in the second EML 8b, and the Fermi level EF of the first EML 8a on the side closer to the HTL 6 is shifted to the center between the VBM of the EML 8 and the isoelectronic level ET of O. Thus, the hole injection barrier to the first EML 8a viewed from the HTL 6 is lowered and the hole injection efficiency is improved. This can further improve the EQE as described above.

### Manufacturing Method for Light-Emitting Element 2

In the present embodiment, the QD 14 is coated two separate times in step S3. Specifically, two kinds of the QD dispersions 38 having different content ratios of the second group VI element are manufactured as the QD dispersions 38 in step S11, and step S31 and step S32 are repeated twice using the respective QD dispersions 38 in step S3.

When the second group VI element is O and O is doped only in the first portion P1 of the first EML 8a, the acid may be added only to the QD dispersion 38 used for forming the first EML 8a.

When the second group VI element is O and the first portion P1 of the first EML 8a and the second portion P2 of the second EML 8b each contain O as the second group VI element, the concentration of the acid added to the QD dispersion 38 used for forming the second EML 8b may be set lower than the concentration of the acid added to the QD dispersion 38 used for forming the first EML 8a. Alternatively, the amount of acid to be added to the QD dispersion 38 used for forming the second EML 8b may be reduced to be smaller than the amount of acid added to the QD dispersion 38 used for forming the first EML 8a.

### Modified Example

The concentration of the sum of the second group VI elements in the base material 16 may be small on the side of the EML 8 closer to the ETL 10 in the thickness direction. However, in this case, the concentration of the sum of the second group VI elements in the base material 16 need not decrease linearly as closer to the ETL 10, and may become smaller stepwise. The concentration of the sum of the second group VI elements in the base material 16 may change continuously or may change stepwise.

In the disclosure, “The concentration of the sum of the second group VI elements in the base material 16 is small on the side of the EML 8 closer to the ETL 10 in the thickness direction” includes both a case where the concentration of the sum of the second group VI elements in the base material 16 becomes linearly smaller in a portion of the EML 8 closer to the ETL 10 in the thickness direction and a case where the concentration of the sum of the second group VI element in the base material 16 becomes smaller stepwise in the portion closer to the ETL 10.

In any case, when the EML 8 is divided into a side closer to the HTL 6 than the center of the EML 8 in the thickness direction and a side farther from the HTL 6 (i.e., the ETL 10 side), the sum of the concentrations of the second group VI element in the base material 16 on the side closer to the HTL 6 than the center of the EML 8 in the thickness direction may be in the range from 1×10¹⁹ atoms/cm³ to 1×10²⁰ atoms/cm³. The sum of the concentrations of the second group VI element in the base material 16 on the side closer to the ETL 10 than the center of the EML 8 in the thickness direction may be in a range from 1×10¹⁶ atoms/cm³ to 1×10¹⁸ atoms/cm³.

FIG. 18 is a cross-sectional view illustrating an example of a schematic configuration of the light-emitting element 2 according to the present modified example.

FIG. 18 illustrates, as an example, a case where the EML 8 has a configuration in which a first EML 8a′, a second EML 8b′, and a third EML 8c′ are layered in this order from the HTL 6 side, and the concentration of the sum of the second group VI elements in the base material 16 becomes smaller stepwise.

In the EML 8 of the light-emitting element 2 illustrated in FIG. 18, the base material 16 includes a first portion P11, a second portion P12, and a third portion P13 having different total concentrations of the second group VI element. The concentration of the sum of the second group VI elements in the second portion P12 is lower than the concentration of the sum of the second group VI elements in the first portion P11, and the concentration of the sum of the second group VI elements in the third portion P13 is lower than the concentration of the sum of the second group VI elements in the second portion P12. In this case, the base material 16 of the first EML 8a′ is the first portion P11, the base material 16 of the second EML 8b′ is the second portion P12, and the base material 16 of the third EML 8c′ is the third portion P13.

The first EML 8a′, the second EML 8b′, and the third EML 8c′ have the same layer thickness, and have the same configuration except that the concentrations of the sum of the second group VI elements in the base material 16 are different from each other as described above. The total layer thickness of the layer thickness of the first EML 8a′, the layer thickness of the second EML 8b′, and the layer thickness of the third EML 8c′ may be larger than the layer thickness of the EML 8 according to the first embodiment, but is desirably the same as the layer thickness of the EML 8 according to the first embodiment. In this case, the highest luminous efficiency can be obtained.

Also in this case, as described above, when the concentration of the second group VI element is relatively high on the side closer to the HTL 6 than on the side closer to the ETL 10, the hole injection efficiency can be improved and the EQE can be further improved.

Also in this case, when the concentration of the sum of the second group VI elements on the side closer to the HTL 6 is relatively high, and, for example, the second group VI element is O as described above, diffusion of O from the EML 8 to the HTL 6 occurs with the lapse of time to suppress an oxygen deficiency of the HTL 6. This makes it possible to provide the light-emitting element 2 having high reliability.

### Manufacturing Method for Light-Emitting Element 2

When the light-emitting element 2 illustrated in FIG. 18 is formed, the QD 14 may be coated three separate times in step S3. Specifically, three kinds of the QD dispersions 38 having different content ratios of the second group VI element are manufactured as the QD dispersion 38 in step S11, and step S31 and step S32 are repeated three times using the respective QD dispersions 38 in step S3. Also in this case, the second group VI element need not be contained in the base material 16 in the third EML 8c′ closest to the ETL 10.

In order to make the concentration of the sum of the second group VI elements in the base material 16 become smaller stepwise in the portion closer to the ETL 10 in the thickness direction of the EML 8, for example, when the second group VI element is O, the concentration of the acid added to the QD dispersion 38 used for forming the EML closer to the ETL 10 may be set to be lower stepwise than the concentration of the acid added to the QD dispersion 38 used for forming the EML closer to the HTL 6. Alternatively, the amount of acid added to the QD dispersion 38 used for forming the EML on the side closer to the ETL 10 may be reduced stepwise from the amount of acid added to the QD dispersion 38 used for forming the EML on the side closer to the HTL 6.

Alternatively, in step S31, while the QD dispersion 38 is continuously supplied and coated onto the HTL 6, acids having different concentrations may be dropped (supplied) a plurality of separate times, or an acid may be dropped (supplied) a plurality of separate times by changing the dropping amount of the acid. For example, by finely controlling the dropping amount of the acid or by dropping the acid while gradually diluting the acid to reduce the concentration, the concentration of the sum of the second group VI elements in the base material 16 can be made gradually smaller (i.e., continuously changed).

### Third Embodiment

The light-emitting element 2 can be preferably used as a light source for a light-emitting device such as a display device or an illumination device, or the like. It is sufficient that the light-emitting device includes at least one light-emitting element 2. In the following, a case where the light-emitting element 2 is used as the light source for the display device will be described as an example.

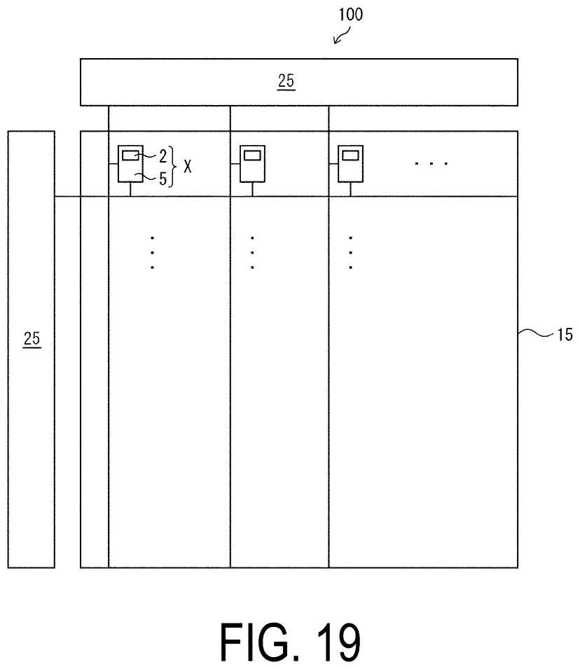

FIG. 19 is a plan view illustrating a configuration example of the display device according to the present embodiment. As illustrated in FIG. 19, a display device 100 includes a display portion 15 including a plurality of subpixels X, and a driver circuit 25 for driving the display portion 15. For example, the subpixel X includes the light-emitting element 2 described in the first or second embodiment and a pixel circuit 5. The display device 100 may be the illumination device.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

1. A light-emitting element comprising:
a light-emitting layer; and
a hole transport layer provided adjacent to the light-emitting layer,
wherein the light-emitting layer includes a base material including at least one kind of inorganic compound and a plurality of quantum dots,
the base material includes, as the inorganic compound, a base compound including at least one kind of first group VI element as a main component, and includes at least one kind of second group VI element having a smaller period number than the first group VI element included in the base compound, and
a concentration of the sum of the second group VI elements in the base material is in a range from 1×10¹⁶ atoms/cm³ to 1×10²⁰ atoms/cm³.

2. The light-emitting element according to claim 1,
wherein the base compound is a group II-VI compound.

3. The light-emitting element according to claim 1,
wherein the first group VI element is at least one kind selected from the group consisting of S, Se, and Te.

4. The light-emitting element according to claim 1,
wherein the quantum dot includes a core and a shell, and
the shell includes the same material as the base compound.

5. The light-emitting element according to claim 1,
wherein the quantum dot includes a core and a shell, and
a band gap of the base material is greater than a band gap of the core or the shell.

6. The light-emitting element according to claim 5,
wherein the band gap of the base material is greater than the band gap of the shell.

7. The light-emitting element according to claim 4,
wherein an average distance between the cores of adjacent ones of the quantum dots is 3 nm or more.

8. The light-emitting element according to claim 1,
wherein the second group VI element is O.

9. The light-emitting element according to claim 1,
wherein a concentration of the sum of the first group VI elements in the base material is 105 times or more higher than a concentration of the sum of the second group VI elements in the base material.

10. The light-emitting element according to claim 1, further comprising:
an electron transport layer provided adjacent to the light-emitting layer on an opposite side of the hole transport layer across the light-emitting layer,
wherein a concentration of the sum of the second group VI elements in the base material on a side closer to the hole transport layer than a center of the light-emitting layer in a thickness direction is higher than a concentration of the sum of the second group VI elements in the base material on a side closer to the electron transport layer than the center of the light-emitting layer in the thickness direction.

11. The light-emitting element according to claim 10,
wherein a concentration of the sum of the second group VI elements in the base material is small on a side of the light-emitting layer closer to the electron transport layer in the thickness direction.

12. The light-emitting element according to claim 10,
wherein the concentration of the sum of the second group VI elements in the base material on the side closer to the hole transport layer than the center of the light-emitting layer in the thickness direction is in a range from 1×10¹⁹ atom/cm³ to 1×10²⁰ atom/cm³, and
the concentration of the sum of the second group VI elements in the base material on the side closer to the electron transport layer than the center of the light-emitting layer in the thickness direction is in a range from 1×10¹⁶ atoms/cm³ to 1×10¹⁸ atoms/cm³.

13. The light-emitting element according to claim 10,
wherein the second group VI element is mixed only into the base material on the side closer to the hole transport layer than the center of the light-emitting layer in the thickness direction.

14. The light-emitting element according to claim 13,
wherein the second group VI element is mixed over ½ of a thickness of the light-emitting layer.

15. The light-emitting element according to claim 1,
wherein the base material further includes at least one kind of a halogen element.

16. The light-emitting element according to claim 15,
wherein a concentration of the sum of the halogen elements in the base material is 1×10¹⁶ atoms/cm³ or more.

17. The light-emitting element according to claim 16,
wherein the concentration of the sum of the halogen elements in the base material is 1×10¹⁹ atoms/cm³ or less.

18. The light-emitting element according to claim 15,
wherein a mean value of concentrations of the sum of the halogen elements in a region within 1 nm from an outermost surface of each of the plurality of quantum dots in the base material is 10% or more higher than a mean value of concentrations of the sum of the halogen elements in a region at a distance exceeding 1 nm from the outermost surface of each of the plurality of quantum dots in the base material.

19. The light-emitting element according to claim 1,
wherein the base material includes at least one of Mg and Li.

20. The light-emitting element according to claim 1,
wherein a space between the plurality of quantum dots in the light-emitting layer is filled with the base material.

21. (canceled)

22. (canceled)

23. (canceled)

24. (canceled)
